(19) United States
(12) Patent Application Publication
(10) Pub. No.: US 2026/0122918 A1
(43) Pub. Date: Apr. 30, 2026

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventor: HYUN-MOOK CHOI, Suwon-si (KR)

(21) Appl. No.: 19/335,392

(22) Filed: Sep. 22, 2025

(30) Foreign Application Priority Data
Oct. 30, 2024 (KR) 10-2024-0151096

(51) Int. Cl. H10B 63/00

(52) U.S. Cl. CPC H10B 63/845; H10B 63/34

(57) ABSTRACT

A three-dimensional (3D) semiconductor memory device may include a stack including gate electrodes and insulating layers which alternately stacked on a substrate in a vertical direction perpendicular to a top surface of the substrate, a vertical channel pattern in a channel hole extending in the stack, an ion storage pattern on a side surface of the vertical channel pattern, an electrolytic pattern between the vertical channel pattern and the ion storage pattern, and ion absorption patterns between the vertical channel pattern and the electrolytic pattern. Each of the ion storage pattern and the electrolytic pattern may extend in the vertical direction, and the ion absorption patterns may be spaced apart from each other in the vertical direction.

### CROSS-REFERENCE TO RELATED APPLICATIONS

This U.S. non-provisional patent application claims priority under 35 U.S.C. § 119 to Korean Patent Application No. 10-2024-0151096, filed on Oct. 30, 2024, in the Korean Intellectual Property Office, the entire contents of which are hereby incorporated by reference.

### BACKGROUND

The present disclosure relates generally to a three-dimensional semiconductor memory device, and in particular, a nonvolatile three-dimensional semiconductor memory device including a vertical structure, a method of fabricating the same, and an electronic system including the same.

A semiconductor device capable of storing a large amount of data may be required as a data storage of an electronic system. Higher integration of semiconductor devices may be required to satisfy consumer demand for large data storing capacity, superior performance, and inexpensive prices. In the case of two-dimensional or planar semiconductor devices, since their integration is mainly determined by the area occupied by a unit memory cell, integration is may be influenced by the level of a fine pattern forming technology. However, expensive process equipment that may be needed to increase pattern fineness may set a practical limitation on increasing integration for two-dimensional or planar semiconductor devices. Thus, three-dimensional semiconductor memory devices including three-dimensionally arranged memory cells have been proposed.

### SUMMARY

An embodiment of the inventive concept provides a three-dimensional semiconductor memory device with improved electrical and reliability characteristics.

An embodiment of the inventive concept provides an electronic system including a three-dimensional semiconductor memory device with improved electrical and reliability characteristics.

According to an embodiment of the inventive concept, a three-dimensional (3D) semiconductor memory device may include a stack including gate electrodes and insulating layers, which are alternately stacked on a substrate, a vertical channel pattern in a channel hole penetrating (i.e., extending in) the stack, an ion storage pattern on a side surface of the vertical channel pattern, an electrolytic pattern between the vertical channel pattern and the ion storage pattern, and ion absorption patterns between the vertical channel pattern and the electrolytic pattern. Each of the ion storage pattern and the electrolytic pattern may be extended in a vertical direction perpendicular to a top surface of the substrate, and the ion absorption patterns may be spaced apart from each other in the vertical direction.

According to an embodiment of the inventive concept, a three-dimensional (3D) semiconductor memory device may include a stack including gate electrodes and insulating layers, which are alternately stacked on a substrate, a vertical channel pattern in a channel hole penetrating the stack, ion storage patterns on a side surface of the vertical channel pattern, and an electrolytic pattern between the vertical channel pattern and the ion storage patterns. The ion storage patterns may be spaced apart from each other in a vertical direction perpendicular to a top surface of the substrate.

According to an embodiment of the inventive concept, an electronic system may include a three-dimensional semiconductor memory device, which includes a substrate including a cell array region and a connection region, a peripheral circuit structure including peripheral circuits, on the substrate, a cell array structure including a stack including gate electrodes and insulating layers, which are alternately stacked on the peripheral circuit structure, and vertical structures penetrating the stack, and an input/output pad electrically connected to the peripheral circuits, and a controller, which is electrically connected to the three-dimensional semiconductor memory device through the input/output pad and is configured to control the three-dimensional semiconductor memory device. Each of the vertical structures may include a vertical channel pattern in a channel hole penetrating the stack, an ion storage pattern on a side surface of the vertical channel pattern, an electrolytic pattern between the vertical channel pattern and the ion storage patterns, and ion absorption patterns between the vertical channel pattern and the electrolytic pattern. The ion absorption patterns may be spaced apart from each other in a direction perpendicular to a top surface of the substrate.

### BRIEF DESCRIPTION OF THE DRAWINGS

The above and other aspects, features, and advantages of the present disclosure will be more clearly understood from the following detailed description, taken in conjunction with the accompanying drawings, wherein like reference numerals (when used) indicate corresponding elements throughout the several views, and in which:

FIG. 1 is a diagram schematically illustrating an electronic system including a three-dimensional semiconductor memory device according to an embodiment of the inventive concept;

FIG. 2 is a perspective view schematically illustrating an electronic system including a three-dimensional semiconductor memory device according to an embodiment of the inventive concept;

FIGS. 3 and 4 are schematic cross-sectional views taken along a line I-I′ of FIG. 2 to illustrate a semiconductor package including a three-dimensional semiconductor memory device, according to an embodiment of the inventive concept;

FIG. 5 is a schematic plan view illustrating a three-dimensional semiconductor memory device according to an embodiment of the inventive concept;

FIGS. 6A and 6B are schematic cross-sectional views taken along lines A-A′ and B-B′, respectively, of FIG. 5 to illustrate a three-dimensional semiconductor memory device according to an embodiment of the inventive concept;

FIG. 7A is an enlarged schematic cross-sectional view illustrating a portion (e.g., region P1 of FIG. 6A) of a three-dimensional semiconductor memory device according to an embodiment of the inventive concept;

FIG. 7B is a schematic plan view taken along a line C-C′ of FIG. 7A;

FIGS. 8 and 9 are enlarged schematic cross-sectional views illustrating a portion (e.g., region P1 of FIG. 6A) of a three-dimensional semiconductor memory device according to an embodiment of the inventive concept;

FIG. 10A is an enlarged schematic cross-sectional view illustrating a portion (e.g., region P1 of FIG. 6A) of a three-dimensional semiconductor memory device according to an embodiment of the inventive concept;

FIG. 10B is a schematic plan view taken along a line D-D′ of FIG. 10A;

FIG. 11 is an enlarged schematic cross-sectional view illustrating a portion (e.g., region P1 of FIG. 6A) of a three-dimensional semiconductor memory device according to an embodiment of the inventive concept;

FIG. 12 is an enlarged schematic cross-sectional view illustrating a portion (e.g., region P2 of FIG. 6A) of a three-dimensional semiconductor memory device according to an embodiment of the inventive concept;

FIG. 13 is a schematic cross-sectional view illustrating a three-dimensional semiconductor memory device according to an embodiment of the inventive concept;

FIGS. 14A to 19B are schematic cross-sectional views illustrating intermediate processes in an example method of fabricating a three-dimensional semiconductor memory device according to an embodiment of the inventive concept; and

FIGS. 20A to 21B are schematic cross-sectional views illustrating intermediate processes in an example method of fabricating a three-dimensional semiconductor memory device according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus repeated descriptions will be omitted.

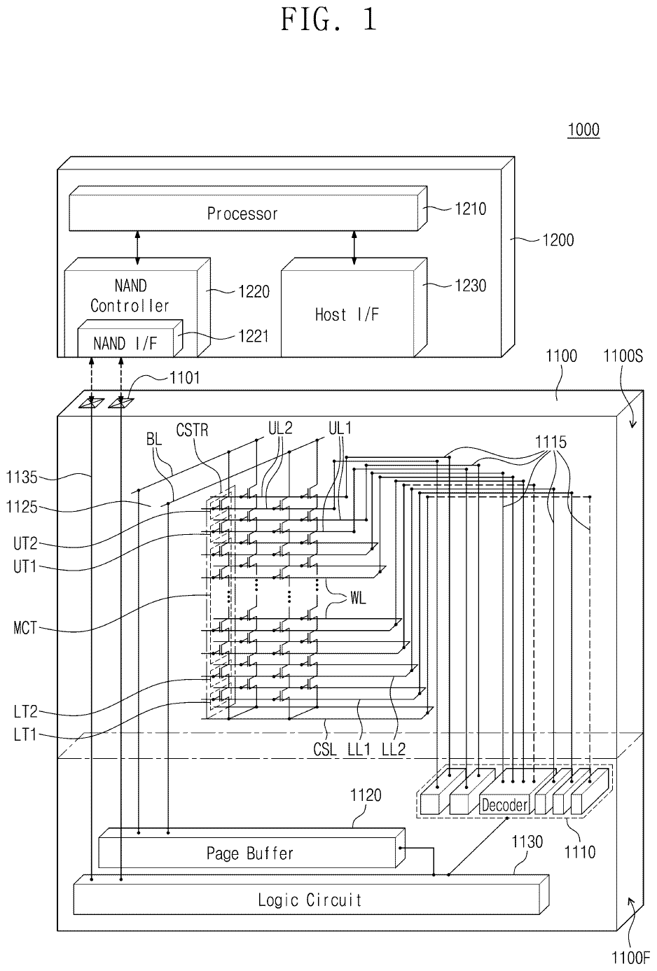

FIG. 1 is a diagram schematically illustrating an electronic system including a three-dimensional semiconductor memory device according to an embodiment of the inventive concept.

Referring to FIG. 1, an electronic system 1000 according to an embodiment of the inventive concept may include a three-dimensional semiconductor memory device 1100 and a controller 1200, which is electrically connected to the three-dimensional semiconductor memory device 1100. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. The electronic system 1000 may be a storage device including the three-dimensional semiconductor memory device 1100 or an electronic device including a storage device. For example, the electronic system 1000 may be a solid state drive (SSD) device, a universal serial bus (USB), a computing system, a medical system, or a communication system, in which the three-dimensional semiconductor memory device 1100 is provided. In an embodiment, a plurality of three-dimensional semiconductor memory devices 1100 may be provided.

The three-dimensional semiconductor memory device 1100 may be a nonvolatile memory device (e.g., a NAND FLASH memory device). The three-dimensional semiconductor memory device 1100 may include a first structure 1100F and a second structure 1100S on the first structure 1100F. Alternatively, the first structure 1100F may be disposed beside the second structure 1100S.

The first structure 1100F may be a peripheral circuit structure, which includes a decoder circuit 1110, a page buffer 1120, and a logic circuit 1130. The second structure 1100S may be a memory cell structure including bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit lines BL, and a plurality of memory cell transistors MCT disposed between the lower transistors LT1 and LT2 and the upper transistors UT1 and UT2.

For example, each of the memory cell transistors MCT may be an electrochemical random access memory (ECRAM), which includes a data storing element with a solid electrolyte and an ion storage. Since the data storing element with the solid electrolyte and the ion storage is used, the three-dimensional semiconductor memory device may be operated with a relatively low power and a fast operation speed. The word lines WL may serve as gate electrodes of the memory cell transistors MCT. By using a voltage difference between the word lines WL and the channel regions of the memory cell transistors MCT, an electrical resistance of the channel regions of the memory cell transistors MCT may be changed, and this may be used for writing or erasing data in the memory cell transistors MCT.

For example, the upper transistors UT1 and UT2 may include string selection transistors, and the lower transistors LT1 and LT2 may include ground selection transistors. The gate lower lines LL1 and LL2 may be used as respective gate electrodes of the lower transistors LT1 and LT2. The gate upper lines UL1 and UL2 may be used as respective gate electrodes of the upper transistors UT1 and UT2. In an embodiment, the number of the lower transistors LT1 and LT2 and the number of the upper transistors UT1 and UT2 may be variously changed.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F to the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may execute a control operation on at least one memory cell transistor that is selected from the memory cell transistors MCT. The decoder circuit 1110 and the page buffer 1120 may be controlled by the logic circuit 1130. The three-dimensional semiconductor memory device 1100 may communicate with the controller 1200 through one or more input/output pads 1101, which are electrically connected to the logic circuit 1130. The input/output pad(s) 1101 may be electrically connected to the logic circuit 1130 through a corresponding input/output connection line 1135, which is extended from the first structure 1100F to the second structure 1100S.

The first structure 1100F may further include a voltage generator. The voltage generator may generate a program voltage, a read voltage, a pass voltage, a verification voltage, and so forth, which are needed to operate the memory cell strings CSTR. Here, the program voltage may be a relatively high voltage (e.g., 20V to 40V), compared with the read voltage, the pass voltage, and the verification voltage.

The first structure 1100F may include high voltage transistors and low voltage transistors. The decoder circuit 1110 may include pass transistors which are connected to the word lines WL of the memory cell strings CSTR. The pass transistors may include high-voltage transistors which can stand a high voltage (e.g., the program voltage) applied to the word lines WL during a programming operation). The page buffer 1120 may also include high-voltage transistors which can stand the high voltage.

The controller 1200 may include a processor 1210, a NAND controller 1220, and a host interface (I/F) 1230. In an embodiment, a plurality of three-dimensional semiconductor memory devices 1100 may be provided, and the controller 1200 may be configured to control the three-dimensional semiconductor memory devices 1100.

The processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands, which will be used to control the three-dimensional semiconductor memory device 1100 and data, which will be written in or read from the memory cell transistors MCT. The host interface 1230 may be configured to allow for communication between the electronic system 1000 and an external host (not explicitly shown). If a control command is provided from an external host through the host interface 1230, the processor 1210 may control the three-dimensional semiconductor memory device 1100 in response to the control command.

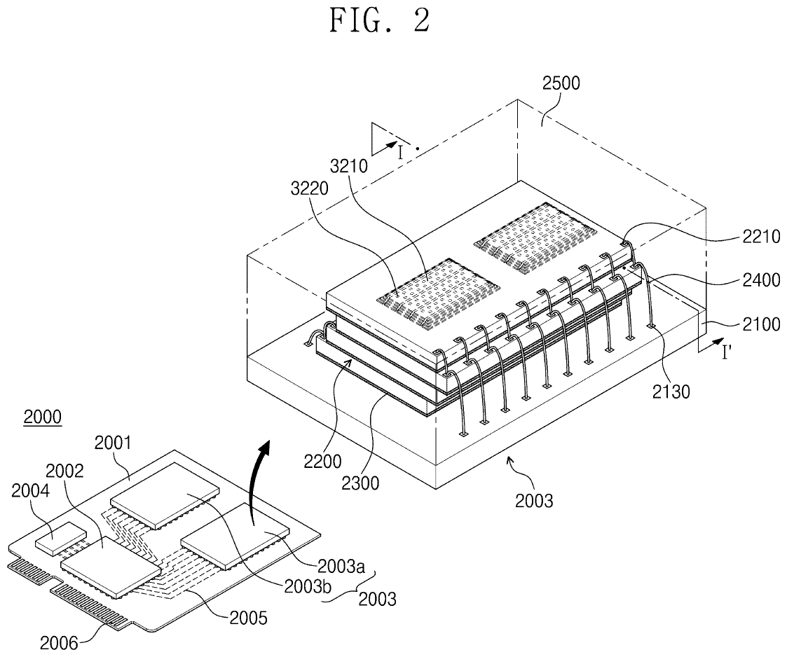

FIG. 2 is a perspective view schematically illustrating an electronic system including a three-dimensional semiconductor memory device according to an embodiment of the inventive concept.

Referring to FIG. 2, an electronic system 2000 may include a main substrate 2001 and a controller 2002, one or more semiconductor packages 2003, and a DRAM 2004, which are provided (e.g., mounted) on the main substrate 2001. The semiconductor package 2003, the DRAM 2004, and the controller 2002 may be electrically connected to each other through interconnection patterns 2005, which are provided (e.g., formed) in the main substrate 2001.

The main substrate 2001 may include a connector 2006, which includes a plurality of pins coupled to an external host. In the connector 2006, the number and the arrangement of the pins may be changed depending on a communication interface between the electronic system 2000 and the external host. For example, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by an electric power, which is supplied from the external host through the connector 2006. The electronic system 2000 may further include a power management integrated circuit (PMIC) that is used to separately supply the electric power, which is provided from the external host, to the controller 2002 and the semiconductor package 2003.

The controller 2002 may control a writing or reading operation on the semiconductor package 2003 and may improve an operation speed (e.g., data transfer rate) of the electronic system 2000.

The DRAM 2004 may be a buffer memory that is used to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other on the main substrate 2001. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400. The term “cover” (or “covering,” or like terms), as may be used herein, is intended to broadly refer to an element, structure or layer that is on or over another element, structure or layer, either directly or with one or more other intervening elements, structures or layers therebetween.

The package substrate 2100 may be a printed circuit board including upper pads 2130. Each of the semiconductor chips 2200 may include an input/output pad 2210. The input/output pad 2210 may correspond to the input/output pad 1101 of FIG. 1. Each of the semiconductor chips 2200 may include stacks 3210 and vertical structures 3220. Each of the semiconductor chips 2200 may include a three-dimensional semiconductor memory device, which will be described below.

For example, the connection structure 2400 may be a bonding wire electrically connecting the input/output pad 2210 to the upper pads 2130. That is, in each of the first and second semiconductor packages 2003a and 2003b, the semiconductor chips 2200 may be electrically connected to each other in a bonding wire manner and may be electrically connected to the upper pads 2130 of the package substrate 2100. In an embodiment, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In an embodiment, the controller 2002 and the semiconductor chips 2200 may be included in a single package, but the inventive concept is not limited to this example. For example, the controller 2002 and the semiconductor chips 2200 may be mounted on a separate interposer substrate, which is prepared regardless of the main substrate 2001, and may be connected to each other through interconnection lines, which are provided in the interposer substrate.

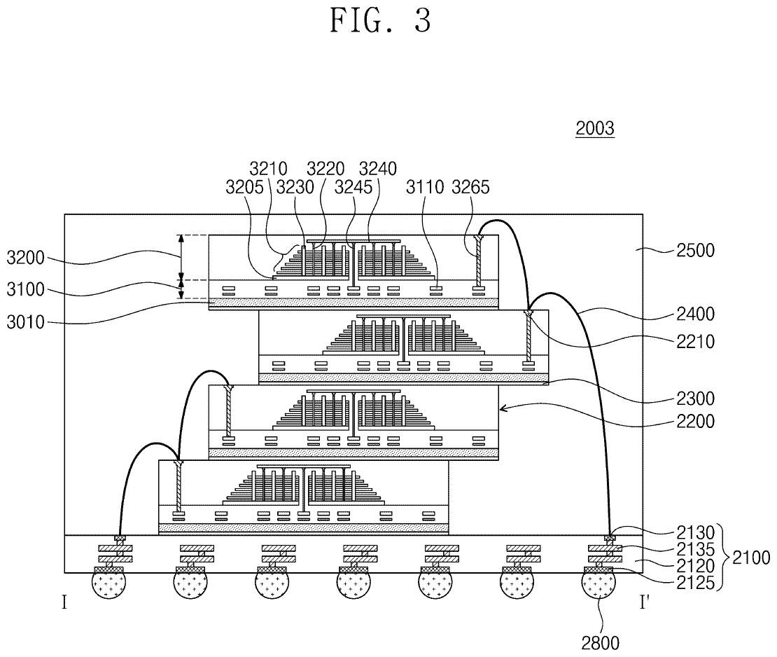

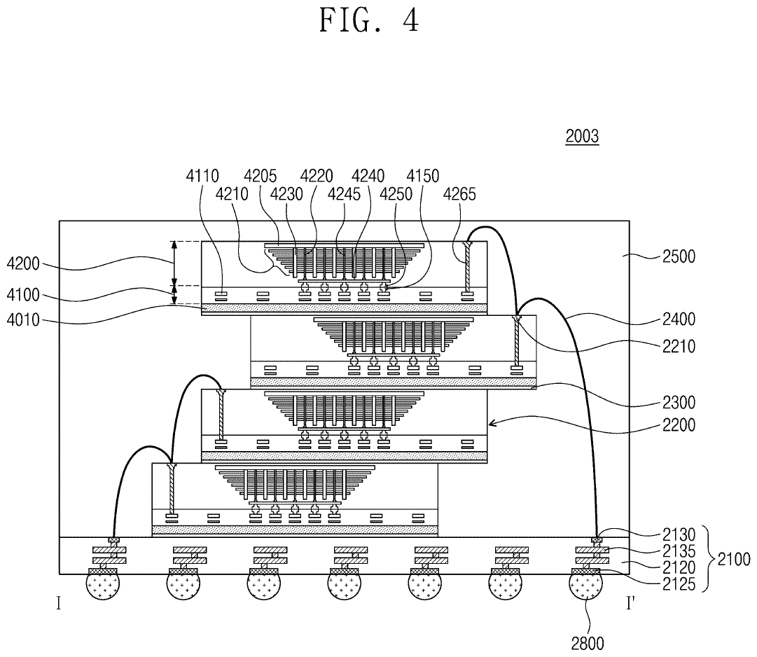

FIGS. 3 and 4 are schematic cross-sectional views taken along a line I-I′ of FIG. 2 to illustrate a semiconductor package including a three-dimensional semiconductor memory device, according to an embodiment of the inventive concept.

Referring to FIG. 3, the package substrate 2100 of the semiconductor package 2003 may be a printed circuit board. The package substrate 2100 may include a package substrate body portion 2120, the upper pads 2130 disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 of FIG. 2 through conductive connecting portions 2800 (e.g., solder balls).

Each of the semiconductor chips 2200 may include a semiconductor substrate 3010 and a first structure 3100 and a second structure 3200, which are sequentially stacked on the semiconductor substrate 3010 in a vertical direction perpendicular to a surface of the semiconductor substrate 3010. The first structure 3100 may include a peripheral circuit region, in which peripheral lines 3110 are provided. The second structure 3200 may include a source structure 3205, a stack 3210 on the source structure 3205, vertical structures 3220 and separation structures 3230, which are provided to penetrate the stack 3210, bit lines 3240, which are electrically connected to the vertical structures 3220, and cell contact plugs 3235, which are electrically connected to the word lines WL (e.g., see FIG. 1) of the stack 3210.

Each of the semiconductor chips 2200 may include penetration lines 3245, which are electrically connected to the peripheral lines 3110 of the first structure 3100 and extend into the second structure 3200. The penetration lines 3245 may be disposed outside the stack 3210 and may be further extended to penetrate the stack 3210. Each of the semiconductor chips 2200 may further include the input/output pad 2210 electrically connected to the peripheral lines 3110 of the first structure 3100.

Referring to FIG. 4, the semiconductor chips 2200 of the semiconductor package 2003 may include a semiconductor substrate 4010, a first structure 4100 on the semiconductor substrate 4010, and a second structure 4200, which is provided on the first structure 4100 and is bonded to the first structure 4100 in a wafer bonding manner.

The first structure 4100 may include a peripheral circuit region, in which a peripheral line 4110 and first junction structures 4150 are provided. The second structure 4200 may include a source structure 4205, a stack 4210, which is provided between the source structure 4205 and the first structure 4100, vertical structures 4220 and a separation structure 4230, which are provided to penetrate (i.e., extend in or through) the stack 4210, and second junction structures 4250, which are electrically and respectively connected to the vertical structures 4220 and the word lines WL (e.g., see FIG. 1) of the stack 4210. In an embodiment, the second junction structures 4250 may be electrically connected to the vertical structures 4220 and the word lines WL (e.g., see FIG. 1) through bit lines 4240 and cell contact plugs 4235, which are electrically connected to the vertical structures 4220 and the word lines WL, respectively. The first junction structures 4150 of the first structure 4100 and the second junction structures 4250 of the second structure 4200 may be bonded to each other and may be in contact with each other. For example, the first junction structures 4150 and the second junction structures 4250 may be formed of or include copper (Cu).

Referring back to FIGS. 3 and 4, the first structure 3100 or 4100 and the second structure 3200 or 4200 may correspond to the first and second structures 1100F and 1100S of FIG. 1. The semiconductor chips 2200 may be electrically connected to each other by the connection structures 2400, which may be provided in the form of bonding wires, but the inventive concept is not limited to this example. For example, the semiconductor chips 2200 may be electrically connected to each other by penetration electrodes extending in or through the semiconductor chips 2200.

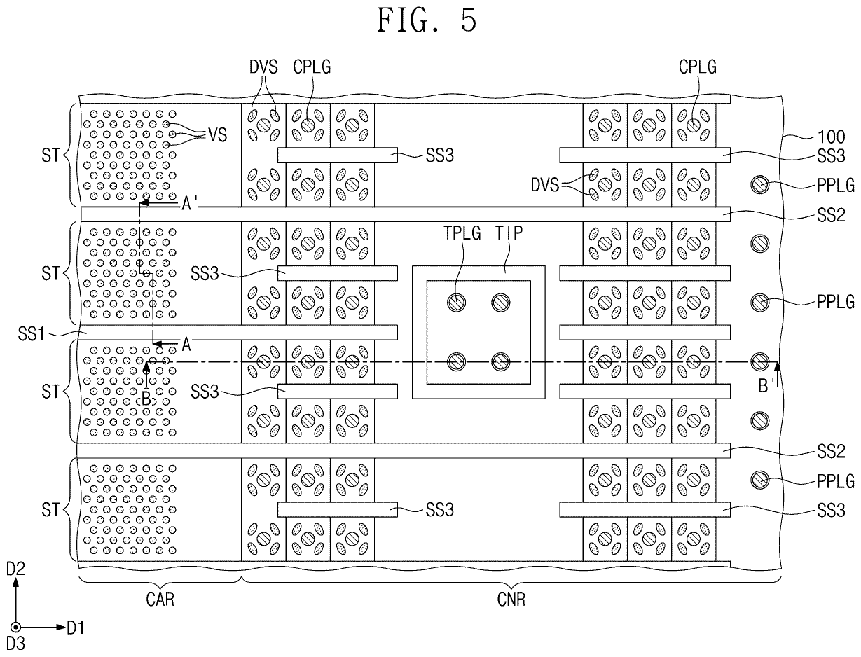

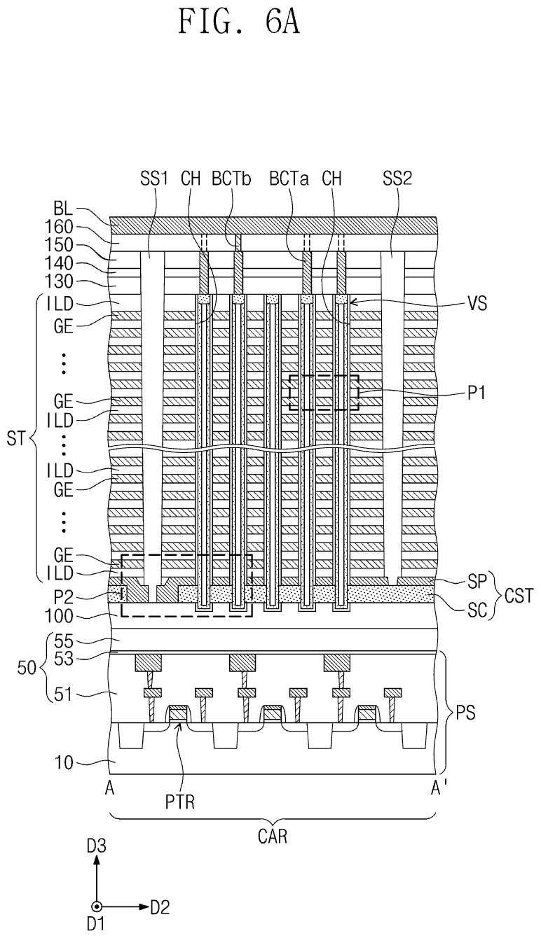

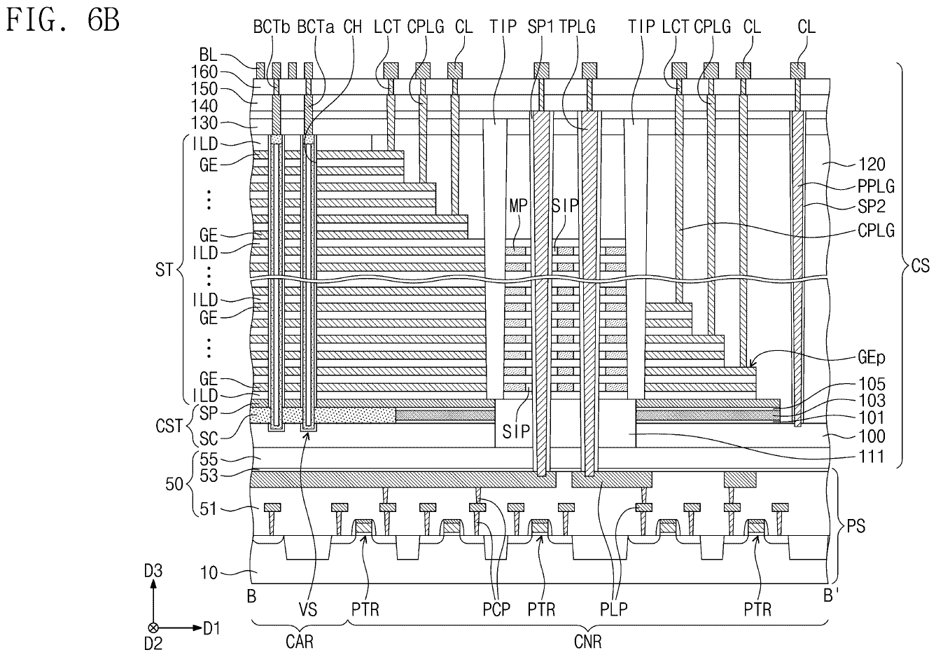

FIG. 5 is a schematic plan view illustrating a three-dimensional semiconductor memory device according to an embodiment of the inventive concept. FIGS. 6A and 6B are schematic cross-sectional views taken along lines A-A′ and B-B′, respectively, of FIG. 5 to illustrate a three-dimensional semiconductor memory device according to an embodiment of the inventive concept.

Referring to FIGS. 5, 6A, and 6B, the three-dimensional semiconductor memory device may include a peripheral circuit structure PS and a cell array structure CS on the peripheral circuit structure PS. For example, the peripheral circuit structure PS may correspond to the first structures 1100F, 3100, and 4100 of FIGS. 1, 3, and 4, respectively, and the cell array structure CS may correspond to the second structures 1100S, 3200, and 4200 of FIGS. 1, 3, and 4, respectively.

The peripheral circuit structure PS may include a first substrate 10, peripheral circuits PTR integrated on the first substrate 10, and a lower insulating layer 50 covering the peripheral circuits PTR.

The first substrate 10 may include a cell array region CAR and a connection region CNR. The first substrate 10 may extend in a first direction D1 from the cell array region CAR toward the connection region CNR and in a second direction D2 crossing the first direction D1. The first and second directions D1 and D2 may be parallel to a top surface of the first substrate 10, and a third direction D3 may be perpendicular to the top surface of the first substrate 10 and orthogonal to the first and second directions D1 and D2. In an embodiment, the first, second, and third directions D1, D2, and D3 may be orthogonal to each other. In the present specification, the first and second directions D1 and D2 may be referred to as horizontal directions, and the third direction D3 may be referred to as a vertical direction, depending on an orientation of the semiconductor memory device.

When viewed in a plan view, the connection region CNR may extend from the cell array region CAR in the first direction D1. Vertical structures VS and bit lines BL, which are electrically connected to the vertical structures VS, may be provided on the cell array region CAR. In an embodiment, a stepwise structure, which is formed by pad portions GEp to be described below, and cell contact plugs CPLG, which are connected to the pad portions GEp, may be provided on the connection region CNR.

For example, the first substrate 10 may be a silicon substrate, a silicon-germanium substrate, a germanium substrate, or a single-crystalline epitaxial layer grown on a single-crystalline silicon substrate.

A device isolation layer may be provided in the first substrate 10 to define an active region, and the peripheral circuits PTR may be placed on the active region. In an embodiment, the peripheral circuits PTR may include row and column decoders, a page buffer, and a control circuit. The peripheral circuits PTR may include n-channel metal-oxide-semiconductor (NMOS) and p-channel metal-oxide-semiconductor (PMOS) transistors. Peripheral circuit lines PLP may be electrically connected to the peripheral circuits PTR through peripheral contact plugs PCP. The peripheral circuit lines PLP may correspond to the peripheral lines 3110 and 4110 of FIGS. 3 and 4, respectively.

The lower insulating layer 50 may be provided on the first substrate 10 to cover the peripheral circuits PTR, the peripheral contact plugs PCP, and the peripheral circuit lines PLP. The lower insulating layer 50 may include a first lower insulating layer 51, a second lower insulating layer 55, and an etch stop layer 53 between the first and second lower insulating layers 51 and 55. The etch stop layer 53 may include an insulating material different from the first and second lower insulating layers 51 and 55 and may cover top surfaces of the uppermost ones of the peripheral circuit lines PLP. For example, the lower insulating layer 50 may be formed at least one of silicon oxide, silicon nitride, silicon oxynitride, and/or low dielectric constant (low-k) dielectric materials.

The cell array structure CS may include a second substrate 100, a source structure CST, stack ST, the vertical structures VS, dummy vertical structures DVS, the cell contact plugs CPLG, penetration contact plugs TPLG, the bit lines BL, and conductive lines CL.

The second substrate 100 may be provided on a top surface of the lower insulating layer 50. The second substrate 100 may be formed of or include at least one of semiconductor, insulating, or conductive materials. The second substrate 100 may be formed of or include a semiconductor material, which is doped with impurities of a first conductivity type (e.g., n-type), and/or an undoped (i.e., intrinsic) semiconductor material. The second substrate 100 may have at least one of single crystalline, amorphous, or polycrystalline structures.

The source structure CST may be provided between the second substrate 100 and the stack ST. The source structure CST may be parallel to a top surface of the second substrate 100 and may be extended parallel to the stack ST or in the first direction D1, in the cell array region CAR. The source structure CST may correspond to the common source line CSL of FIG. 1 or the source structures 3205 and 4205 of FIGS. 3 and 4.

The source structure CST may include a source conductive pattern SC and a conductive supporting pattern SP on the source conductive pattern SC. In the cell array region CAR, the source conductive pattern SC may be disposed between the second substrate 100 and the stack ST. In the cell array region CAR, the source conductive pattern SC may have an opening exposing the top surface of the second substrate 100. The term “exposing” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The opening of the source conductive pattern SC may have a circular or bar shape, and in an embodiment, a plurality of openings may be provided. In an embodiment, the source conductive pattern SC may be formed of or include a semiconductor material that is doped with impurities of a first conductivity type.

In the connection region CNR, dummy insulating patterns may be provided between the second substrate 100 and the stack ST. The dummy insulating patterns may be located at substantially the same level as the source conductive pattern SC. In the present specification, the term “level” may mean a height from the top surface of the first substrate 10 or the second substrate 100 in the third direction D3.

The dummy insulating patterns may include a first dummy insulating pattern 101, a second dummy insulating pattern 103, and a third dummy insulating pattern 105 that are sequentially stacked in the third direction D3. The second dummy insulating pattern 103 may be formed of or include an insulating material different from the first and third dummy insulating patterns 101 and 105. The second dummy insulating pattern 103 may have a thickness in the third direction D3 greater than a thickness in the third direction D3 of the first and third dummy insulating patterns 101 and 105. For example, the first, second, and third dummy insulating patterns 101, 103, and 105 may be formed of or include at least one of silicon oxide, silicon nitride, silicon oxynitride, silicon carbide, or silicon germanium.

In the cell array region CAR, the conductive supporting pattern SP may cover a top surface of the source conductive pattern SC and may fill a portion of the opening of the source conductive pattern SC. Thus, the conductive supporting pattern SP may have a recessed top surface, in the opening of the source conductive pattern SC. The term “fill” (or “fills,” or like terms) is intended to refer to either completely filling a defined space (e.g., the opening of the source conductive pattern SC) or partially filling the defined space; that is, the defined space need not be entirely filled but may, for example, be partially filled or have voids or other spaces throughout. In the connection region CNR, the conductive supporting pattern SP may cover the top surfaces of the dummy insulating patterns. In an embodiment, the conductive supporting pattern SP may be formed of or include a semiconductor material, which is doped with impurities of a first conductivity type (e.g., n-type), and/or an undoped (i.e., intrinsic) semiconductor material.

In the connection region CNR, a mold insulating pattern 111 may be provided to penetrate the conductive supporting pattern SP, the dummy insulating patterns, and the second substrate 100. The mold insulating pattern 111 may be in contact with the lower insulating layer 50 and may have a top surface that is substantially coplanar with a top surface of the conductive supporting pattern SP.

A structure or stack ST may be provided on the source structure CST. The stack ST may extend from the cell array region CAR to the connection region CNR in the first direction D1. In an embodiment, a plurality of stacks ST may be spaced apart from each other in the second direction D2. The stack ST may correspond to the stacks 3210 and 4210 of FIGS. 3 and 4, respectively.

The stack ST may include gate electrodes GE and insulating layers ILD, which are alternately stacked in the third direction D3 that is perpendicular to the first and second directions D1 and D2 which are not parallel to each other. In the connection region CNR, the gate electrodes GE may have pad portions GEp. The pad portions GEp of the gate electrodes GE may be placed at different positions in horizontal and vertical directions. For example, the stack ST may have a stepwise structure in the connection region CNR.

Each of the gate electrodes GE may have substantially the same thickness in the third direction D3. The insulating layers ILD may have different thicknesses from each other in the third direction D3. For example, a thickness of an uppermost one of the insulating layers ILD in the third direction D3 may be larger than a thickness of each of the remaining ones of the insulating layers ILD in the third direction D3. Each of the remaining ones of the insulating layers ILD may have substantially the same thickness in the third direction D3.

Lengths of the gate electrodes GE in the first direction D1 may decrease as a distance from the second substrate 100 in the third direction D3 increases. For example, the uppermost one of the gate electrodes GE furthest from the second substrate 100 in the third direction D3 may have the smallest length in the first direction D1, and the lowermost one of the gate electrodes GE closest to the second substrate 100 in the third direction D3 may have the largest length in the first direction D1. Similar to the gate electrodes GE, lengths of the insulating layers ILD in the first direction D1 may decrease as a distance from the second substrate 100 in the third direction D3 increases. In an embodiment, a side surface of each of the insulating layers ILD may be aligned to a side surface of one of the gate electrodes GE adjacent thereto.

The gate electrodes GE may be formed of or include at least one of, for example, doped semiconductor materials (e.g., doped silicon), metallic materials (e.g., tungsten, copper, or aluminum), conductive metal nitrides (e.g., titanium nitride or tantalum nitride), or transition metals (e.g., titanium or tantalum). The insulating layers ILD may be formed of or include at least one of silicon oxide, silicon nitride, silicon oxynitride, low-k dielectric materials, high density plasma (HDP) oxide, and/or tetraethyl orthosilicate (TEOS). In an embodiment, the three-dimensional semiconductor memory device may be a vertical-type NAND FLASH memory device, and the gate electrodes GE of the stack ST may correspond to the gate lower lines LL1 and LL2, the word lines WL, and gate upper lines UL1 and UL2 of FIG. 1.

In the connection region CNR, the stack ST may include mold patterns MP and sidewall insulating patterns SIP. Between the insulating layers ILD, each of the mold patterns MP and the sidewall insulating patterns SIP may be located at the same level as the gate electrodes GE, relative to the top surface of the second substrate 100 as a reference layer. The mold patterns MP may be placed between the pad portions GEp of the gate electrodes GE. The sidewall insulating patterns SIP may be placed between the mold patterns MP and the penetration contact plugs TPLG. The sidewall insulating patterns SIP may be provided to enclose portions of the side surfaces of the penetration contact plugs TPLG. When viewed in a plan view, the mold patterns MP and the sidewall insulating patterns SIP may be overlapped with the mold insulating pattern 111 in the third direction D3. As used herein, “an element A overlapping an element B in a direction X” (or similar language) means that there is at least one line that extends in the direction X and intersects both the elements A and B. The mold patterns MP may be formed of or include an insulating material different from the insulating layers ILD. The sidewall insulating patterns SIP may be formed of or include an insulating material different from the mold patterns MP. For example, the mold patterns MP may be formed of or include at least one of silicon nitride, silicon oxynitride, or silicon germanium, and the sidewall insulating patterns SIP may be formed of or include silicon oxide.

In an embodiment, the stack ST may include a first stack and a second stack on the first stack. The first stack may include first gate electrodes and first insulating layers, which are alternately stacked on the second substrate 100 in the third direction D3. The second stack may include second gate electrodes and second insulating layers, which are alternately stacked on the first stack in the third direction D3. The uppermost one of the first insulating layers may be in contact with the lowermost one of the second insulating layers.

In the cell array region CAR, the vertical structures VS may be provided in channel holes CH, respectively, which are provided to penetrate (i.e., extend in or through) the stack ST and the source structure CST. Accordingly, the vertical structures VS may be provided to penetrate a portion of the second substrate 100 and be in contact with the second substrate 100. For example, a bottom surface of each of the vertical structures VS may be placed at a level lower than the top surface of the second substrate 100 and the bottom surface of the source structure CST, but the inventive concept is not limited to this example.

When viewed in a plan view (see, e.g., FIG. 5), the vertical structures VS may be arranged to form a zigzag shape in the first or second direction D1 or D2. The vertical structures VS may not be provided on the connection region CNR. The vertical structures VS may correspond to the vertical structures 3220 and 4220 of FIGS. 3 and 4, respectively, and may correspond to channel regions of the lower transistors LT1 and LT2, the upper transistors UT1 and UT2, and the memory cell transistors MCT of FIG. 1.

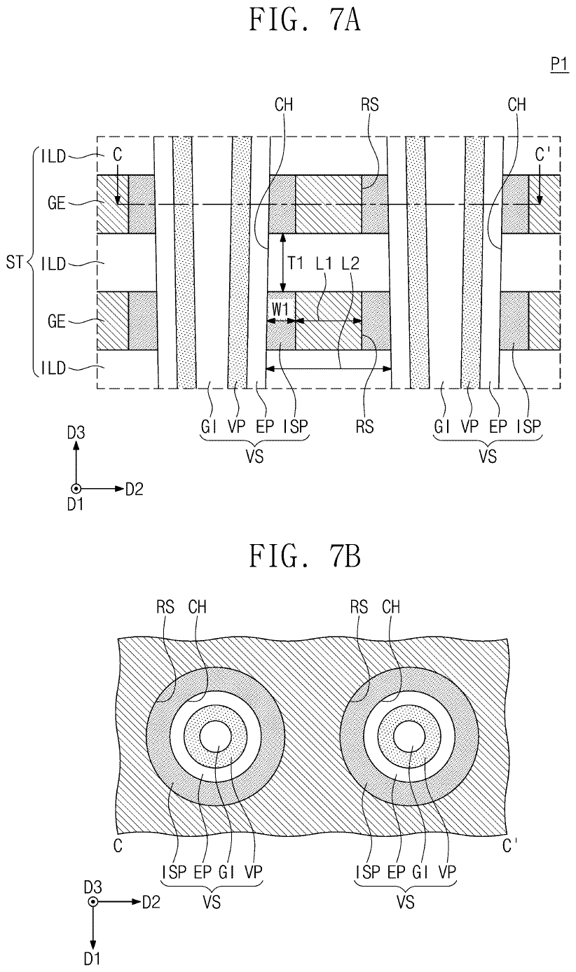

A width of each of the vertical structures VS in the first or second direction D1 or D2 may increase with increasing height in the third direction D3. That is, the uppermost width of each of the vertical structures VS may be greater than the lowermost width of each of the vertical structures VS. However, the inventive concept is not limited to this example, and each of the vertical structures VS may have a constant width in the first or second direction D1 or D2, regardless of its height in the third direction D3. The vertical structures VS will be described in more detail with reference to FIGS. 7A to 12.

In the connection region CNR, a planarization insulating layer 120 may be provided on the stack ST. The planarization insulating layer 120 may cover the stepwise structure of the stack ST. The planarization insulating layer 120 may be located on the pad portions GEp of the gate electrodes GE. The planarization insulating layer 120 may have a substantially flat (i.e., horizontally planar) top surface. The top surface of the planarization insulating layer 120 may be coplanar with the top surface of the stack ST. In other words, the top surface of the planarization insulating layer 120 may be located at the same level as a top surface of the uppermost one of the insulating layers ILD and top surfaces of the vertical channel structures VS, relative to the top surface of the second substrate 100. In an embodiment, the planarization insulating layer 120 may include a single insulating layer or a plurality of stacked insulating layers.

A first interlayer insulating layer 130 may be provided on the planarization insulating layer 120 and the stack ST. The first interlayer insulating layer 130 may cover top surfaces of the vertical structures VS.

In the connection region CNR, a penetration insulating pattern TIP may be provided to penetrate the first interlayer insulating layer 130, the planarization insulating layer 120, and the stack ST. The penetration insulating pattern TIP may be placed between the gate electrodes GE and the mold patterns MP. When viewed in a plan view, the penetration insulating pattern TIP may enclose (i.e., extend around or surround) the mold patterns MP. The penetration insulating pattern TIP may include an insulating layer that is provided to cover a side surface of the stack ST and side surfaces of the mold patterns MP. The penetration insulating pattern TIP may be in contact with the conductive supporting pattern SP and the penetration insulating pattern TIP.

A second interlayer insulating layer 140 may be provided on the first interlayer insulating layer 130. The second interlayer insulating layer 140 may cover a top surface of the first interlayer insulating layer 130 and a top surface of the penetration insulating pattern TIP. A thickness of the second interlayer insulating layer 140 in the third direction D3 may be less than a thickness of the first interlayer insulating layer 130 in the third direction D3. For example, the second interlayer insulating layer 140 may be formed of or include an insulating material different from the first interlayer insulating layer 130.

In the connection region CNR, the penetration contact plugs TPLG may penetrate the first and second interlayer insulating layers 130 and 140, the planarization insulating layer 120, the stack ST, and the mold insulating pattern 111. The penetration contact plugs TPLG may be electrically connected to the peripheral circuit lines PLP of the peripheral circuit structure PS. When viewed in a plan view, the penetration contact plugs TPLG may be placed inside the penetration insulating pattern TIP. A first spacer SP1 may be provided to enclose a side surface of each of the penetration contact plugs TPLG, and here, the first spacer SP1 may be formed of or include an insulating material.

In the connection region CNR, peripheral contact plugs PPLG may be provided to penetrate the first and second interlayer insulating layers 130 and 140 and the planarization insulating layer 120. The peripheral contact plugs PPLG may be connected to the second substrate 100. The peripheral contact plugs PPLG may be spaced apart from the stack ST in the first direction D1. Alternatively, the peripheral contact plugs PPLG may be connected to the conductive supporting pattern SP of the source structure CST. Top surfaces of the peripheral contact plugs PPLG may be coplanar with top surfaces of the penetration contact plugs TPLG. A second spacer SP2 may be provided to enclose a side surface of each of the peripheral contact plugs PPLG, and here, the second spacer SP2 may be formed of or include an insulating material.

A third interlayer insulating layer 150 may be provided on the second interlayer insulating layer 140. The third interlayer insulating layer 150 may cover the top surfaces of the penetration contact plugs TPLG and the top surfaces of the peripheral contact plugs PPLG.

First and second separation structures SS1 and SS2 may be provided on the second substrate 100 to penetrate the first to third interlayer insulating layers 130, 140, and 150 and the stack ST. Each of the first and second separation structures SS1 and SS2 may include an insulating layer covering the side surface of the stack ST. Each of the first and second separation structures SS1 and SS2 may include a single layer or may have a multi-layered structure. Top surfaces of the first and second separation structures SS1 and SS2 may be positioned at substantially the same level.

The first separation structure SS1 may be extended from the cell array region CAR to the connection region CNR in the first direction D1. The first separation structure SS1 may be disposed between the second separation structures SS2. The first separation structure SS1 may be provided to penetrate a portion of the conductive supporting pattern SP filling the opening of the source conductive pattern SC. The first separation structure SS1 may be in contact with the second substrate 100.

The second separation structures SS2 may be extended from the cell array region CAR to the connection region CNR in the first direction D1. The second separation structures SS2 may be spaced apart from each other in the second direction D2. A length of each of the second separation structures SS2 in the first direction D1 may be greater than a length of the first separation structure SS1 in the first direction D1. Since the second separation structures SS2 is placed on the source conductive pattern SC, a vertical length of each of the second separation structures SS2 may be smaller than a vertical length of the first separation structure SS1.

In the connection region CNR, the cell contact plugs CPLG may be provided to penetrate the first to third interlayer insulating layers 130, 140, and 150 and the planarization insulating layer 120. When viewed in a plan view, each of the cell contact plugs CPLG may be placed to be adjacent to the dummy vertical structures DVS. Each of the cell contact plugs CPLG may be connected to the pad portion GEp of a corresponding one of the gate electrodes GE. Top surfaces of the cell contact plugs CPLG may be placed at substantially the same level. Since the stack ST has a stepwise structure, vertical lengths of the cell contact plugs CPLG may decreases as a distance to the cell array region CAR decreases.

In the cell array region CAR, first bit line contact plugs BCTa may be provided to penetrate the first to third interlayer insulating layers 130, 140, and 150. The first bit line contact plugs BCTa may be electrically connected to the vertical structures VS, respectively.

A fourth interlayer insulating layer 160 may be provided on the third interlayer insulating layer 150. The fourth interlayer insulating layer 160 may cover the top surfaces of the cell contact plugs CPLG and the top surfaces of the first bit line contact plugs BCTa.

In the cell array region CAR, second bit line contact plugs BCTb may be provided to penetrate the fourth interlayer insulating layer 160. Each of the second bit line contact plugs BCTb may be placed on and electrically connected to a corresponding one of the first bit line contact plugs BCTa.

In the connection region CNR, contact plugs LCT may be provided to penetrate the fourth interlayer insulating layer 160. Each of the contact plugs LCT may be placed on and electrically connected to a corresponding one of the cell contact plugs CPLG. Some of the contact plugs LCT may be provided to penetrate the third and fourth interlayer insulating layers 150 and 160. In this case, the contact plugs LCT may be electrically connected to the penetration contact plugs TPLG and the peripheral contact plugs PPLG.

In the cell array region CAR, the bit lines BL may be provided on the fourth interlayer insulating layer 160. The bit lines BL may extend in the second direction D2 and may be spaced apart from each other in the first direction D1. Each of the bit lines BL may be electrically connected to a corresponding one of bit line contact plugs BCTa and BCTb. Thus, the bit lines BL may be electrically connected to the vertical structures VS through the bit line contact plugs BCTa and BCTb.

In the connection region CNR, conductive lines CL may be provided on the fourth interlayer insulating layer 160. The conductive lines CL may be spaced apart from each other in the first direction D1. Each of the conductive lines CL may be connected to a corresponding one of the contact plugs LCT. Accordingly, the conductive lines CL may be electrically connected to the cell contact plugs CPLG, the penetration contact plugs TPLG, and the peripheral contact plugs PPLG through the contact plugs LCT.

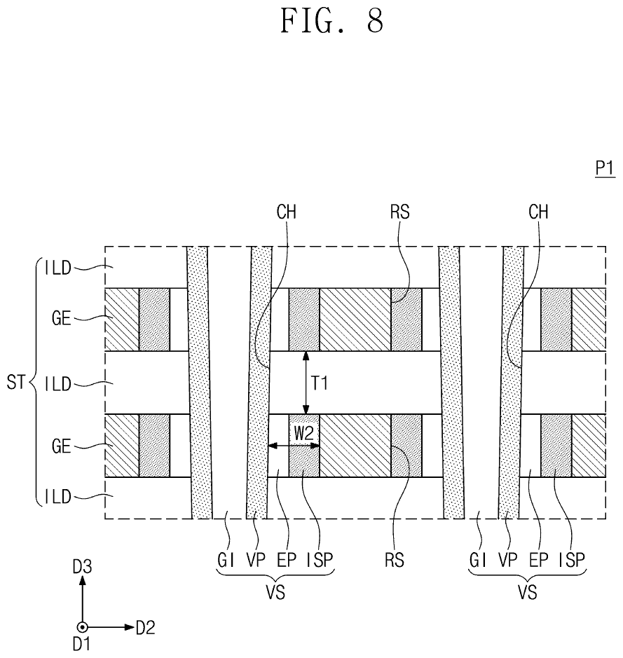

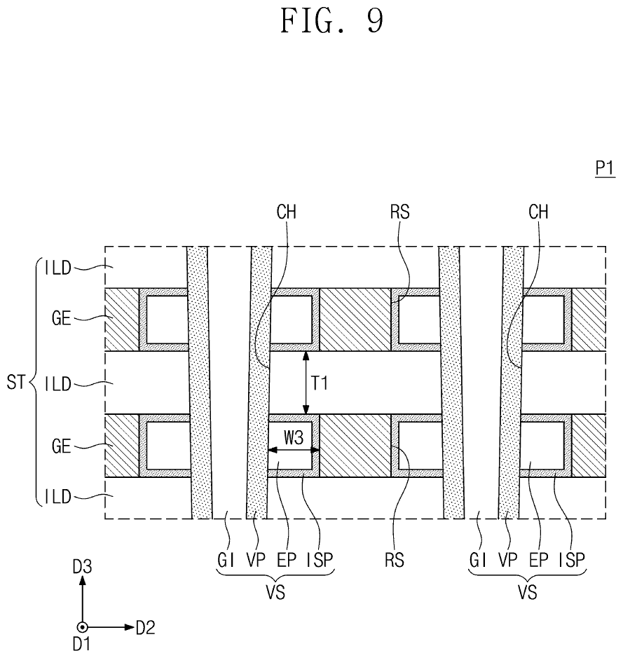

FIG. 7A is an enlarged schematic cross-sectional view illustrating a portion (e.g., region P1 of FIG. 6A) of a three-dimensional semiconductor memory device according to an embodiment of the inventive concept. FIG. 7B is a schematic plan view taken along a line C-C′ of FIG. 7A. FIGS. 8 and 9 are enlarged schematic cross-sectional views illustrating a portion (e.g., region P1 of FIG. 6A) of a three-dimensional semiconductor memory device according to an embodiment of the inventive concept.

Referring to FIGS. 7A and 7B, recess regions RS may be further provided in the stack ST. The recess regions RS may extend outwardly from inner side surfaces of the channel holes CH. For example, the recess regions RS may be a region that is recessed in a horizontal direction (e.g., the first and second directions D1 and D2). The recess regions RS may have a depth in the horizontal direction, from the inner side surface of the channel hole CH. A depth of each of the recess regions RS may be a first width W1 of ion storage patterns ISP, which will be described below. The recess regions RS may be located at the same level as the gate electrodes GE of the stack ST in the third direction D3. Each of the recess regions RS may be located between the insulating layers ILD, which are adjacent to each other in the third direction D3. That is, the recess regions RS may be spaced apart from each other in the third direction D3 by a first thickness T1 of each of the insulating layers ILD.

Each of the vertical structures VS may include an electrolytic pattern EP, a vertical channel pattern VP, and a gapfill insulating pattern GI, which are sequentially provided on the inner side surface of the channel hole CH, and the ion storage patterns ISP, which are respectively provided in the recess regions RS. Each of the electrolytic pattern EP, the vertical channel pattern VP, and the gapfill insulating pattern GI may extend in the third direction D3, in the channel holes CH.

The gapfill insulating pattern GI may be placed at a center portion of each of the vertical structures VS. The gapfill insulating pattern GI may fill an internal space enclosed by the vertical channel pattern VP. When viewed in a plan view, the gapfill insulating pattern GI may have a circular shape, but the inventive concept is not limited to this example. The gapfill insulating pattern GI may be formed of or include at least one of, for example, silicon oxide, silicon nitride, silicon oxynitride, and/or low-k dielectric materials.

The vertical channel pattern VP may be placed on a side surface of the gapfill insulating pattern GI. When viewed in a plan view, the vertical channel pattern VP may be provided to enclose the side surface of the gapfill insulating pattern GI and may have a ring shape. The vertical channel pattern VP may be provided to have the shape of hollow cylinder. The vertical channel pattern VP may be used as the channel regions of the upper transistors UT1 and UT2, the memory cell transistors MCT, and the lower transistors LT1 and LT2 of FIG. 1. In an embodiment, the vertical channel pattern VP may be formed of or include at least one of, for example, semiconductor materials (e.g., doped Si, poly-Si, and SiGe), oxide semiconductor materials (e.g., IGZO, Sn-IGZO, WO₃, WSe₂, IWO, CuS₂, CuSe₂, IZO, ZTO, and YZO), or two-dimensional materials (e.g., MoS₂, MoSe₂, and WS₂).

The electrolytic pattern EP may be placed on a side surface of the vertical channel pattern VP. When viewed in a plan view, the electrolytic pattern EP may be provided to enclose the side surface of the vertical channel pattern VP and may have a ring shape. Similar to the vertical channel pattern VP, the electrolytic pattern EP may also have the shape of hollow cylinder. When viewed in plan view, the gapfill insulating pattern GI, the vertical channel pattern VP, and the electrolytic pattern EP may be concentric. The electrolytic pattern EP may be formed of or include at least one of, for example, HfO₂, ZrO₂, LiPON, H2_{S}O₄-PVA, LiₓSi_{y}O_{z}, CeO₂, or Li₃PS₄. In an embodiment, the electrolytic pattern EP may include a plurality of oxygen vacancies therein. Thus, the electrolytic pattern EP may serve as a pathway for oxygen ions, which are carriers in the ion storage patterns ISP.

The ion storage patterns ISP may be placed between the electrolytic pattern EP and the gate electrodes GE. Each of the ion storage patterns ISP may have the first width W1, in a corresponding one of the recess regions RS. Each of the ion storage patterns ISP may be in contact with a portion of the electrolytic pattern EP. When viewed in a plan view, each of the ion storage patterns ISP may be provided to enclose the electrolytic pattern EP and may have a ring shape. In an embodiment, the ion storage patterns ISP may be formed of or include at least one of WO₃, Si, Pd, Ni, Pt, TiH₂, MgH₂, LiCoO₂, or LiNiO₂. In an embodiment, the ion storage patterns ISP may include carriers therein, and the carriers may be oxygen ions.

The ion storage patterns ISP, which are adjacent to each other in the third direction D3, may be spaced apart from each other in the third direction D3 by the first thickness T1 of the insulating layers ILD and may be vertically overlapped with each other. In addition, the ion storage patterns ISP, which are adjacent to each other in the third direction D3, may be in contact with a corresponding one of the vertical channel patterns VP. Alternatively, the ion storage patterns ISP, which are adjacent to each other in the second direction D2, may be located at the same level and may be in contact with different ones of the vertical channel patterns VP. For example, each of the insulating layers ILD may be placed between the ion storage patterns ISP, which are adjacent to each other in the third direction D3, and each of the gate electrodes GE may be placed between the ion storage patterns ISP, which are adjacent to each other in the second direction D2. Accordingly, the ion storage patterns ISP may be vertically overlapped with portions of the insulating layers ILD.

The gate electrodes GE of the stack ST may have a first length L1 in the second direction D2, between the vertical structures VS, which are adjacent to each other in the second direction D2. The insulating layers ILD of the stack ST may have a second length L2 in the second direction D2, between the vertical structures VS which are adjacent to each other in the second direction D2. In an embodiment, the first length L1 may be smaller than the second length L2. The sum of the first length L1 and twice the first width W1 may be substantially equal to the second length L2. In other words, the ion storage patterns ISP may be placed at the same level as the gate electrodes GE and between the electrolytic pattern EP and the gate electrodes GE. Thus, between the vertical structures VS, a horizontal length of the gate electrodes GE may be smaller than a horizontal length of the insulating layers ILD.

Referring to FIG. 8, the recess regions RS of the stack ST may have a depth in the second direction D2 that is given as a second width W2, when measured from the inner side surfaces of the channel holes CH. The second width W2 may be larger than the first width W1 of FIG. 7A, but the inventive concept is not limited to this example. For example, the second width W2 may be equal to the sum of widths, in the second direction D2, of the electrolytic pattern EP and the ion storage pattern ISP, which are adjacent to each other.

Each of the vertical structures VS may include a plurality of electrolytic patterns EP. For example, the electrolytic patterns EP may be provided in the recess regions RS, respectively. The electrolytic patterns EP may be provided to enclose the side surface of the vertical channel pattern VP. Similar to the ion storage patterns ISP, the electrolytic patterns EP may be spaced apart from each other in the third direction D3. Each of the electrolytic patterns EP may be located at the same level as a corresponding one of the gate electrodes GE and a corresponding one of the ion storage patterns ISP.

The electrolytic patterns EP, which are adjacent to each other in the third direction D3, may be spaced apart from each other by the first thickness T1 of the insulating layers ILD. The electrolytic patterns EP, which are adjacent to each other in the third direction D3, may be vertically overlapped with each other and may be in contact with a corresponding one of the vertical structures VS. For example, each of the insulating layers ILD may be placed between the electrolytic patterns EP, which are adjacent to each other in the third direction D3. Thus, the electrolytic patterns EP may be vertically overlapped with a portion of the insulating layers ILD.

Referring to FIG. 9, the recess regions RS of the stack ST may have a depth, in the second direction D2, that is given as a third width W3, when measured from the inner side surfaces of the channel holes CH. The third width W3 may be larger than the first width W1 of FIG. 7A and may be substantially equal to the second width W2 of FIG. 8. However, the inventive concept is not limited to this example.

The ion storage patterns ISP of the vertical structures VS may be respectively placed between the electrolytic patterns EP and the gate electrodes GE. Each of the ion storage patterns ISP may cover an inner surface of the recess region RS with a uniform or constant thickness. For example, each of the ion storage patterns ISP may be extended from a side surface of the corresponding electrolytic pattern EP to top and bottom surfaces of the corresponding insulating pattern EP. Each of the ion storage patterns ISP may cover the side, top, and bottom surfaces of adjacent ones of the electrolytic patterns EP. Thus, at least a portion of the ion storage patterns ISP may be in contact with the vertical channel pattern VP.

Referring back to FIGS. 7A to 9, the carriers in the ion storage patterns ISP may be moved to or from the vertical channel pattern VP through one or more electrolytic patterns EP. That is, the carriers in the ion storage patterns ISP may be reversibly moved by a voltage difference between the vertical channel pattern VP and the gate electrodes GE. Thus, the electrical resistance of the vertical channel pattern VP may be changed, and in an embodiment, this change may be permanently maintained. Thus, a three-dimensional semiconductor memory device according to an embodiment of the inventive concept may be operated as a nonvolatile memory device.

In a three-dimensional semiconductor memory device according to an embodiment of the inventive concept, the ion storage patterns ISP may be spaced apart from each other in the vertical direction. Since the ion storage patterns ISP are physically separated from each other, only the carriers in a selected one of the ion storage patterns ISP may be easily moved, while the carriers in undesired ones of the ion storage patterns ISP may be prevented from moving. Accordingly, the electrical characteristics of the three-dimensional semiconductor memory device may be improved.

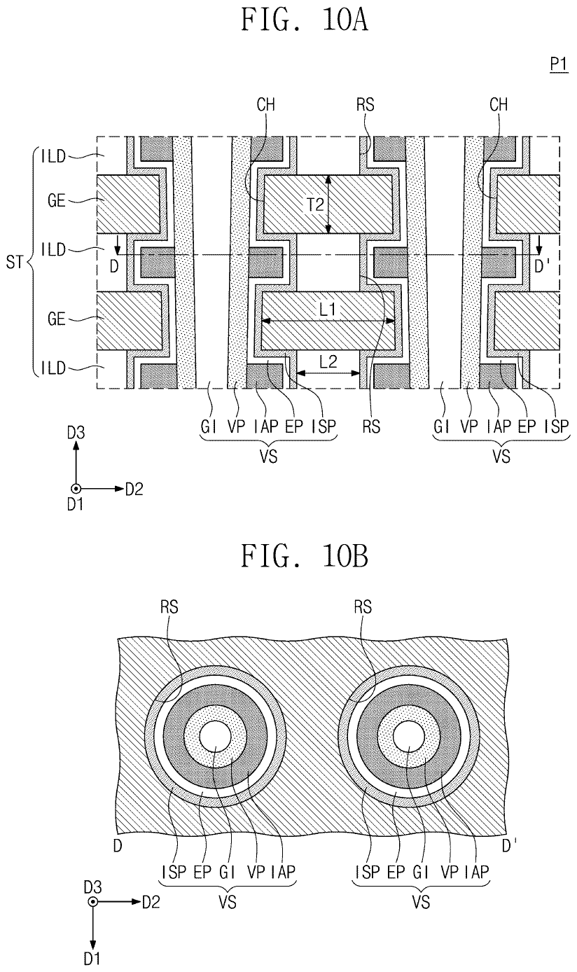

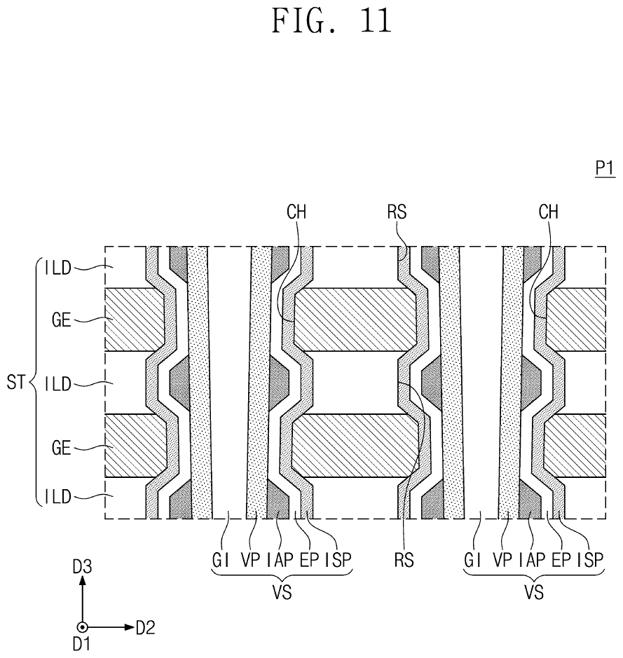

FIG. 10A is an enlarged schematic cross-sectional view illustrating a portion (e.g., region P1 of FIG. 6A) of a three-dimensional semiconductor memory device according to an embodiment of the inventive concept. FIG. 10B is a schematic plan view taken along a line D-D′ of FIG. 10A. FIG. 11 is an enlarged schematic cross-sectional view illustrating a portion (e.g., region P1 of FIG. 6A) of a three-dimensional semiconductor memory device according to an embodiment of the inventive concept.

Referring to FIGS. 10A and 10B, each of the recess regions RS, which are provided in the stack ST, may be a region that is recessed from the inner side surface of the channel hole CH in a horizontal direction (e.g., the first and second directions D1 and D2). The recess regions RS may have a depth in the horizontal direction, from the inner side surface of the channel hole CH. The recess regions RS may be placed at the same level, in the third direction D3, as the insulating layers ILD of the stack ST. Each of the recess regions RS may be located between the gate electrodes GE, which are adjacent to each other in the third direction D3. That is, the recess regions RS may be spaced apart from each other in the third direction D3 by a second thickness T2 of each of the gate electrodes GE.

Each of the vertical structures VS may include the ion storage pattern ISP, the electrolytic pattern EP, ion absorption patterns IAP, the vertical channel pattern VP, and the gapfill insulating pattern GI, which are sequentially provided on inner surfaces of the channel holes CH and the recess regions RS. In the channel hole CH, each of the vertical channel pattern VP and the gapfill insulating pattern GI may be extended in the third direction D3. Each of the ion storage pattern ISP and the electrolytic pattern EP may be extended along inner surfaces of the channel holes CH and the recess regions RS and in the third direction D3.

The gapfill insulating pattern GI and the vertical channel pattern VP may be substantially the same as those described with reference to FIGS. 7A and 7B.

The ion absorption patterns IAP may be placed on the side surface of the vertical channel pattern VP. When viewed in a plan view, the ion absorption patterns IAP may be provided to enclose (i.e., extend around) the vertical channel pattern VP and may have a ring shape. Each of the ion absorption patterns IAP may be located at the same level as a corresponding one of the recess regions RS. Thus, the ion absorption patterns IAP may be spaced apart from each other in the third direction D3. In an embodiment, the ion absorption patterns IAP may be formed of or include at least one of Ti, Er, Co, or Cd. In an embodiment, the ion absorption patterns IAP may absorb carriers of the ion storage pattern ISP. In the case where the carriers in the ion storage pattern ISP are oxygen ions, the ion absorption patterns IAP may absorb the oxygen ions and may form oxide.

The ion absorption patterns IAP, which are adjacent to each other in the third direction D3, may be vertically overlapped with each other. In addition, the ion absorption patterns IAP, which are adjacent to each other in the third direction D3, may be in contact with a corresponding one of the vertical channel patterns VP. The ion absorption patterns IAP, which are adjacent to each other in the second direction D2, may be placed at the same level and may be in contact with different ones of the vertical channel patterns VP. For example, each of the gate electrodes GE may be placed between the ion absorption patterns IAP, which are adjacent to each other in the third direction D3, and each of the insulating layers ILD may be placed between the ion absorption patterns IAP, which are adjacent to each other in the second direction D2. Accordingly, the ion absorption patterns IAP may be spaced apart from the gate electrodes GE in the third direction D3 and may be vertically overlapped with portions of the gate electrodes GE.

The electrolytic pattern EP may be placed on the side surface of the vertical channel pattern VP and the side surfaces of the ion absorption patterns IAP. The electrolytic pattern EP may cover the side surface of the vertical channel pattern VP and the side surfaces of the ion absorption patterns IAP. For example, a portion of the electrolytic pattern EP may be in contact with the vertical channel pattern VP, and a remaining portion of the electrolytic pattern EP may be in contact with the ion absorption patterns IAP. The electrolytic pattern EP may extend into regions between the vertical channel pattern VP and the gate electrodes GE and between the ion absorption patterns IAP and the insulating layers ILD. For example, the electrolytic pattern EP may extend along the channel holes CH and the recess regions RS and may have an uneven profile. When viewed in a plan view, the electrolytic pattern EP may be provided to enclose the vertical channel pattern VP and the ion absorption patterns IAP.

The ion storage pattern ISP may be placed on a side surface of the electrolytic pattern EP to cover inner surfaces of the channel holes CH and the recess regions RS. The ion storage pattern ISP may extend into regions between the electrolytic pattern EP and the gate electrodes GE and between the electrolytic pattern EP and the insulating layers ILD. For example, the ion storage pattern ISP may be formed to have an uneven profile in the channel holes CH and the recess regions RS. The ion storage pattern ISP may be in contact with the gate electrodes GE and the insulating layers ILD. The ion storage pattern ISP may be in contact with a portion of each of the top and bottom surfaces of the gate electrodes GE, in the recess regions RS. When viewed in a plan view, the ion storage pattern ISP may enclose the electrolytic pattern EP and to have a ring shape.

The gate electrodes GE of the stack ST may have the first length L1 in the second direction D2, between the vertical structures VS, which are adjacent to each other in the second direction D2. The insulating layers ILD of the stack ST may have the second length L2 in the second direction D2, between the vertical structures VS, which are adjacent to each other in the second direction D2. In an embodiment, the first length L1 may be larger than the second length L2. That is, the ion absorption patterns IAP may be placed between the insulating layers ILD and the vertical channel pattern VP, at the same level in the third direction D3 as the insulating layers ILD. Accordingly, between the vertical structures VS, a horizontal length of the gate electrodes GE may be larger than a horizontal length of the insulating layers ILD.

Referring to FIG. 11, each of the recess regions RS, which are provided in the stack ST, may have a shape that is convex toward the insulating layers ILD. An inner surface of each of the recess regions RS may have a curved shape or may be composed of a plurality of linear portions. For example, each of the recess regions RS may have a trapezoidal shape, when viewed in a cross-sectional view.

The ion storage pattern ISP and the electrolytic pattern EP may be sequentially provided on inner side surfaces of the channel holes CH and the recess regions RS. Each of the ion storage pattern ISP and the electrolytic pattern EP may extend along the channel holes CH and the recess regions RS and in the third direction D3. Thus, each of the ion storage pattern ISP and the electrolytic pattern EP may be partially extended in a direction inclined to the third direction D3.

Each of the ion absorption patterns IAP may be placed between the electrolytic pattern EP and the vertical channel pattern VP and may have a substantially similar shape to the recess region RS, when viewed in a cross-sectional view. For example, each of the ion absorption patterns IAP may have a trapezoidal shape, when viewed in a cross-sectional view. However, the inventive concept is not limited to this example, but the ion absorption patterns IAP may be provided in various shapes, depending on the sectional shape of the recess regions RS.

Referring back to FIGS. 10A to 11, the ion absorption patterns IAP may be placed between vertically-adjacent ones of the gate electrodes GE. The ion absorption patterns IAP may absorb the carriers of the ion storage pattern ISP moving in a vertical or diagonal direction. Thus, the carriers in the ion storage pattern ISP may be restricted to moving only in a horizontal direction. In other words, the ion storage pattern ISP may be divided into a plurality of portions, which are chemically separated from each other in a vertical direction, and thus, the carriers in the ion storage pattern ISP may be prevented from moving to the gate electrodes GE adjacent thereto in a vertical direction. This may improve the electrical characteristics of the three-dimensional semiconductor memory device.

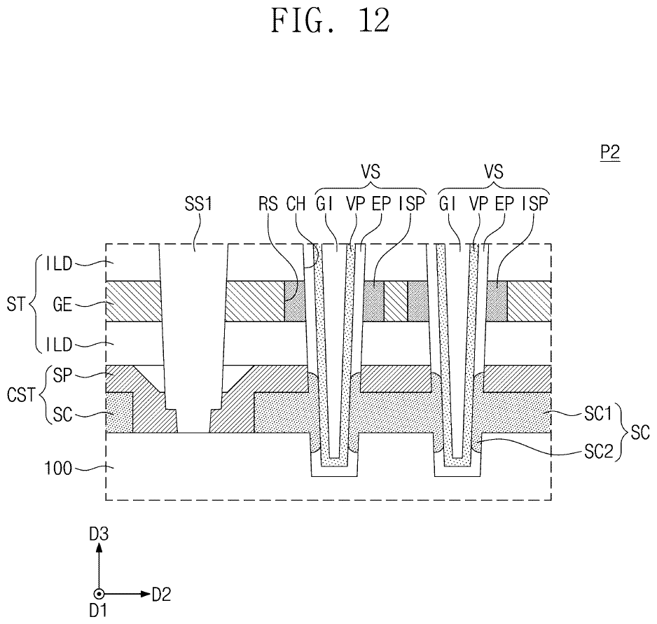

FIG. 12 is an enlarged schematic cross-sectional view illustrating a portion (e.g., region P2 of FIG. 6A) of a three-dimensional semiconductor memory device according to an embodiment of the inventive concept.

Referring to FIG. 12, each of the vertical structures VS may include the vertical channel pattern VP and the electrolytic pattern EP enclosing (i.e., extending around) a side surface of the vertical channel pattern VP. The vertical channel pattern VP may have a pipe or macaroni shape with a closed bottom. A bottom end of the vertical channel pattern VP may have the shape of letter ‘U’ (i.e., U-shaped). A bottom surface of the vertical channel pattern VP may be located at a level lower than the bottom surface of the source conductive pattern SC and the top surface of the second substrate 100 in the third direction D3.

The source conductive pattern SC may include a horizontal portion SC1 and a sidewall portion SC2. The horizontal portion SC1 of the source conductive pattern SC may be parallel to the stack ST, between the conductive supporting pattern SP and the second substrate 100. A top surface of the horizontal portion SC1 of the source conductive pattern SC may be in contact with a bottom surface of the conductive supporting pattern SP, and a bottom surface of the horizontal portion SC1 may be in contact with the top surface of the second substrate 100.

The sidewall portion SC2 of the source conductive pattern SC may protrude vertically from the horizontal portion SC1. The sidewall portion SC2 may be in contact with a portion of the side surface of the vertical channel pattern VP and may enclose the portion of the side surface of the vertical channel pattern VP. That is, the source conductive pattern SC may be in contact with the vertical channel pattern VP. The sidewall portion SC2 may be in contact with a portion of a side surface of the conductive supporting pattern SP. In addition, the sidewall portion SC2 may be in contact with the electrolytic pattern EP, and a surface of the sidewall portion SC2 in contact with the electrolytic pattern EP may have a curved shape. A thickness of the sidewall portion SC2 in the third direction D3 may be larger than a thickness of the horizontal portion SC1 in the third direction D3.

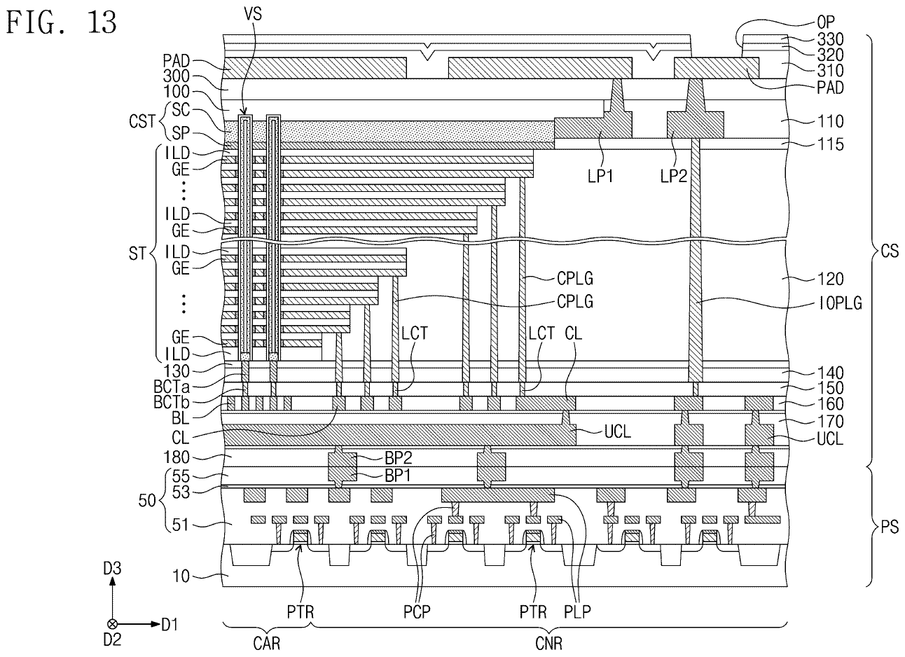

FIG. 13 is a schematic cross-sectional view illustrating a three-dimensional semiconductor memory device according to an embodiment of the inventive concept.

Referring to FIG. 13, the semiconductor device may have a chip-to-chip (C2C) structure. For the C2C structure, an upper chip including the cell array structure CS may be fabricated on a wafer, a lower chip including the peripheral circuit structure PS may be fabricated on another wafer, and the upper chip and the lower chip may be connected to each other through a bonding method. The bonding method may include a hybrid bonding method. In the present specification, a hybrid bonding structure may mean a bonding structure which is formed by two materials, which are of the same kind and are fused at an interface therebetween.

A three-dimensional semiconductor memory device according to an embodiment of the inventive concept may include the peripheral circuit structure PS and the cell array structure CS on the peripheral circuit structure PS. Since the cell array structure CS is placed on the peripheral circuit structure PS, a cell capacity per unit area in the semiconductor device may be increased. In addition, the peripheral circuit structure PS and the cell array structure CS may be separately fabricated and then may be coupled to each other, and in this case, it may prevent peripheral circuits PTR from being damaged by several thermal treatment processes. Accordingly, it may improve the electrical and reliability characteristics of the three-dimensional semiconductor memory device.

The peripheral circuit structure PS may include the first substrate 10, the peripheral circuits PTR, the peripheral circuit lines PLP, the peripheral contact plugs PCP, and the lower insulating layer 50 thereon. The peripheral circuits PTR may be integrated on the top surface of the first substrate 10 and may be configured to control a memory cell array.

The lower insulating layer 50 may be provided on a top surface of the first substrate 10. The lower insulating layer 50 may include the first lower insulating layer 51, the second lower insulating layer 55, and the etch stop layer 53. The first lower insulating layer 51 on the first substrate 10 may cover the peripheral circuits PTR, the peripheral contact plugs PCP, and the peripheral circuit lines PLP. The second lower insulating layer 55 may be located on the first lower insulating layer 51. The etch stop layer 53 may be located between the second lower insulating layer 55 and the first lower insulating layer 51. In an embodiment, the lower insulating layer 50 may be formed of or include at least one of silicon oxide, silicon nitride, silicon oxynitride, and/or low-k dielectric materials.

First bonding pads BP1 may be provided in the second lower insulating layer 55. The second lower insulating layer 55 may not cover top surfaces of the first bonding pads BP1; that is, the top surfaces of the first bonding pads BP1 may be exposed through the second lower insulating layer 55. For example, a top surface of the second lower insulating layer 55 may be substantially coplanar with the top surfaces of the first bonding pads BP1. The first bonding pads BP1 may be electrically connected to the peripheral circuits PTR through the peripheral circuit lines PLP and the peripheral contact plugs PCP.

The cell array structure CS may be provided on the peripheral circuit structure PS. The cell array structure CS may include a memory cell array including memory cells, which are three-dimensionally arranged on the second substrate 100. The cell array structure CS may include the stack ST, the vertical structures VS, the cell contact plugs CPLG, the bit lines BL, and the conductive lines CL. Each of the vertical structures VS may be substantially the same as that described with reference to FIGS. 7A to 11. In addition, the cell array structure CS may further include second bonding pads BP2, an input/output contact plug IOPLG, input/output pads PAD, first and second landing pads LP1 and LP2, an upper insulating layer 300, capping insulating layers 310 and 320, and a passivation layer 330.

A fifth interlayer insulating layer 170 may be provided on the fourth interlayer insulating layer 160 to cover the bit lines BL and the conductive lines CL. Upper conductive lines UCL may be provided in the fifth interlayer insulating layer 170. The upper conductive lines UCL may be electrically connected to the bit lines BL or the conductive lines CL.

A sixth interlayer insulating layer 180 may be provided on the fifth interlayer insulating layer 170, and the second bonding pads BP2 may be provided in the sixth interlayer insulating layer 180. The second bonding pads BP2 may be electrically connected to the upper conductive lines UCL. The second bonding pads BP2 may be electrically and physically connected to the first bonding pads BP1 in a hybrid bonding manner. For example, the first and second bonding pads BP1 and BP2, which are bonded to each other, may have a continuous structure, and there may be no observable interface between the first and second bonding pads BP1 and BP2. The first and second bonding pads BP1 and BP2 may be bonded to form a single object.

In the connection region CNR, an insulating gapfill layer 110 and a pad insulating layer 115 may be provided on the side surface of the second substrate 100 and the side surface of the source structure CST. The pad insulating layer 115 may be placed between the insulating gapfill layer 110 and the planarization insulating layer 120 to cover the first and second landing pads LP1 and LP2. For example, the insulating gapfill layer 110 and the pad insulating layer 115 may be formed of or include at least one of insulating materials (e.g., silicon oxide and silicon nitride).

In the connection region CNR, the first and second landing pads LP1 and LP2 may be provided in the insulating gapfill layer 110. Each of the first and second landing pads LP1 and LP2 may include a via portion, which is in contact with the input/output pad PAD, and a pad portion, which is connected to the via portion. The first landing pad LP1 may be placed to be adjacent to the cell array region CAR, compared with the second landing pad LP2. The pad portion of the first landing pad LP1 may be in contact with the second substrate 100 and the source structure CST. The second landing pad LP2 may be spaced apart from the first landing pad LP1 in the first direction D1. The pad portion of the second landing pad LP2 may be connected to the input/output contact plug IOPLG.

The upper insulating layer 300 may be provided on the second substrate 100 to cover the second substrate 100 and the insulating gapfill layer 110. The input/output pads PAD may be provided on the upper insulating layer 300. The capping insulating layers 310 and 320 and the passivation layer 330 may be sequentially provided on the upper insulating layer 300. The capping insulating layers 310 and 320 may cover the input/output pads PAD. The capping insulating layers 310 and 320 and the passivation layer 330 may have a pad opening OP at least partially exposing the input/output pad PAD. In an embodiment, the capping insulating layers 310 and 320 may be formed of or include silicon nitride or silicon oxynitride, and the passivation layer 330 may be formed of or include a polyimide-based material (e.g., photo sensitive polyimide (PSPI)).

In the connection region CNR, the input/output contact plug IOPLG may be provided to penetrate the first and second interlayer insulating layers 130 and 140, the planarization insulating layer 120, and the pad insulating layer 115. The input/output contact plug IOPLG may be in contact with the second landing pad LP2. For example, the input/output contact plug IOPLG may be electrically connected to the input/output pads PAD through the second landing pad LP2.

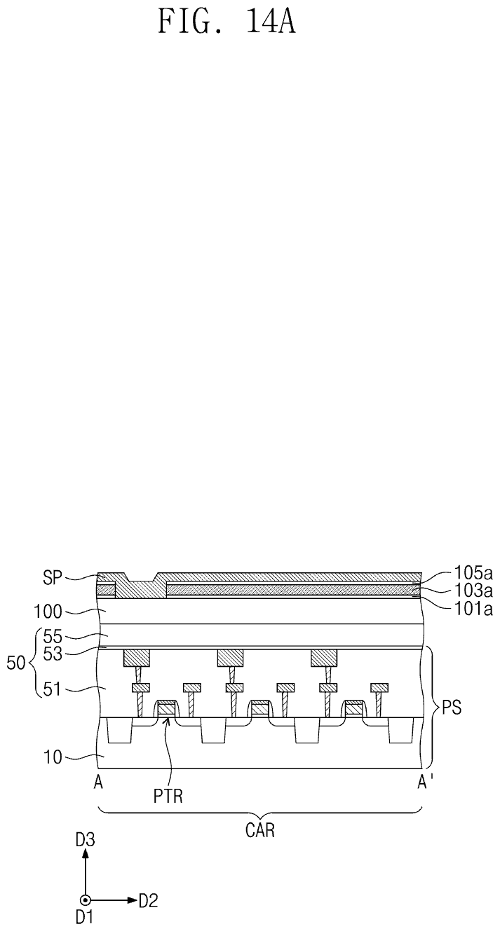

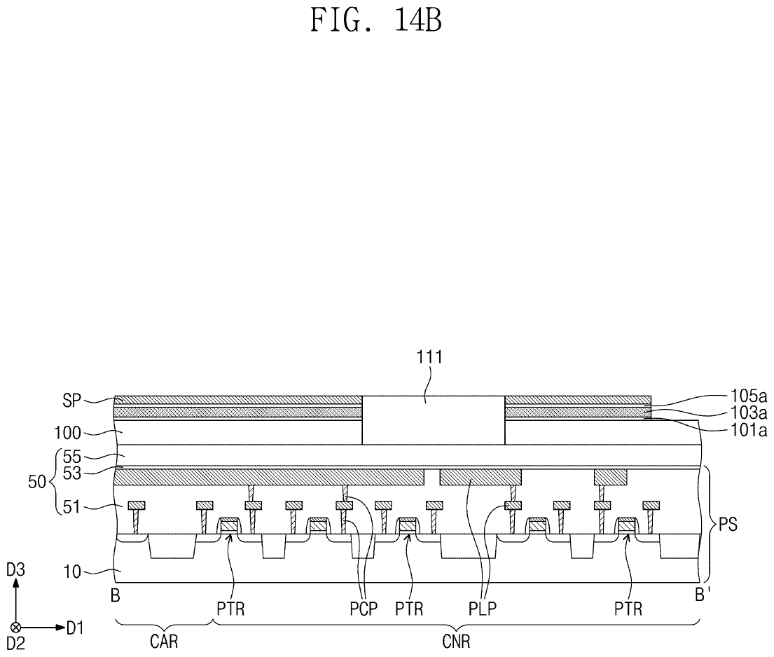

FIGS. 14A to 19B are schematic cross-sectional views illustrating intermediate processes in an example method of fabricating a three-dimensional semiconductor memory device according to an embodiment of the inventive concept. Each of FIGS. 14A, 15A, 16A, 17A, 18A, and 19A is a sectional view taken along a line A-A′ of FIG. 5, and each of FIGS. 14B, 15B, 16B, 17B, 18B, and 19B is a sectional view taken along a line B-B′ of FIG. 5.

Referring to FIGS. 14A and 14B, the peripheral circuit structure PS may be formed. The formation of the peripheral circuit structure PS may include forming the peripheral circuits PTR on the first substrate 10, forming peripheral interconnection structures PCP and PLP connected to the peripheral circuits PTR, and forming the lower insulating layer 50.

The peripheral circuits PTR may be formed on an active region, which is defined by a device isolation layer in the first substrate 10. Here, the peripheral circuits PTR may include MOS transistors, in which the first substrate 10 is used as channel regions thereof.

The lower insulating layer 50 may include the first lower insulating layer 51, the second lower insulating layer 55, and the etch stop layer 53 between the first and second lower insulating layers 51 and 55. The formation of the lower insulating layer 50 may include sequentially forming the first lower insulating layer 51, the etch stop layer 53, and the second lower insulating layer 55 on the first substrate 10. In an embodiment, the lower insulating layer 50 may include a silicon oxide layer, a silicon nitride layer, a silicon oxynitride layer, and/or a low-k dielectric layer.

The formation of the peripheral interconnection structures may include forming the peripheral contact plugs PCP to partially penetrate (i.e., extend in) the first lower insulating layer 51 and forming the peripheral circuit lines PLP electrically connected to the peripheral contact plugs PCP.

Next, the second substrate 100 may be formed on the lower insulating layer 50. The second substrate 100 may be formed by depositing a semiconductor material. In an embodiment, the second substrate 100 may be formed of or include at least one of silicon (Si), germanium (Ge), silicon germanium (SiGe), gallium arsenic (GaAs), indium gallium arsenic (InGaAs), or aluminum gallium arsenic (AlGaAs), although embodiments are not limited thereto. The second substrate 100 may be formed of or include at least one of doped and/or undoped (e.g., intrinsic) semiconductor materials. The second substrate 100 may have at least one of single crystalline, amorphous, or polycrystalline structures.

A first dummy insulating layer 101a, a second dummy insulating layer 103a, and a third dummy insulating layer 105a may be sequentially formed on the second substrate 100. The first dummy insulating layer 101a may be formed by thermally oxidizing the top surface of the second substrate 100 or depositing a silicon oxide layer. The second dummy insulating layer 103a may be formed of or include a material having an etch selectivity with respect to the first dummy insulating layer 101a and the third dummy insulating layer 105a. For example, the second dummy insulating layer 103a may be formed of or include at least one of silicon nitride, silicon oxynitride, silicon carbide, or silicon germanium. The third dummy insulating layer 105a may be formed by depositing a silicon oxide layer on the second dummy insulating layer 103a.

The first to third dummy insulating layers 101a, 103a, and 105a may have an opening exposing a portion of the top surface of the second substrate 100. The formation of the opening may include forming a mask pattern and etching the first to third dummy insulating layers 101a, 103a, and 105a using the mask pattern to expose the portion of the second substrate 100.

Next, the conductive supporting pattern SP may be deposited to have a uniform or constant thickness on the third dummy insulating layer 105a. The conductive supporting pattern SP may fill the opening of the first to third dummy insulating layers 101a, 103a, and 105a. Thus, the conductive supporting pattern SP may have a recessed top surface in the opening. In the opening, the conductive supporting pattern SP may be in contact with the second substrate 100.

The mold insulating pattern 111 may be formed to penetrate the second substrate 100, the first to third dummy insulating layers 101a, 103a, and 105a, and the conductive supporting pattern SP. A bottom surface of the mold insulating pattern 111 may contact a top surface of the second lower insulating layer 55. The formation of the mold insulating pattern 111 may include forming a mask pattern on the conductive supporting pattern SP to expose a portion of the connection region CNR, performing an etching process using the mask pattern to form a hole penetrating the second substrate 100, the first to third dummy insulating layers 101a, 103a, and 105a, and the conductive supporting pattern SP, filling the hole with an insulating material, and performing a planarization process on the insulating material to expose the top surface of the conductive supporting pattern SP.

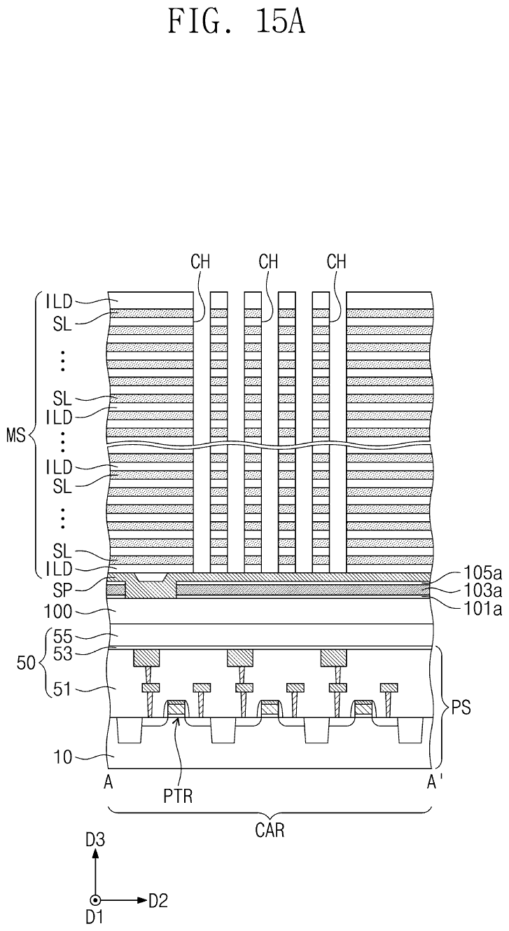

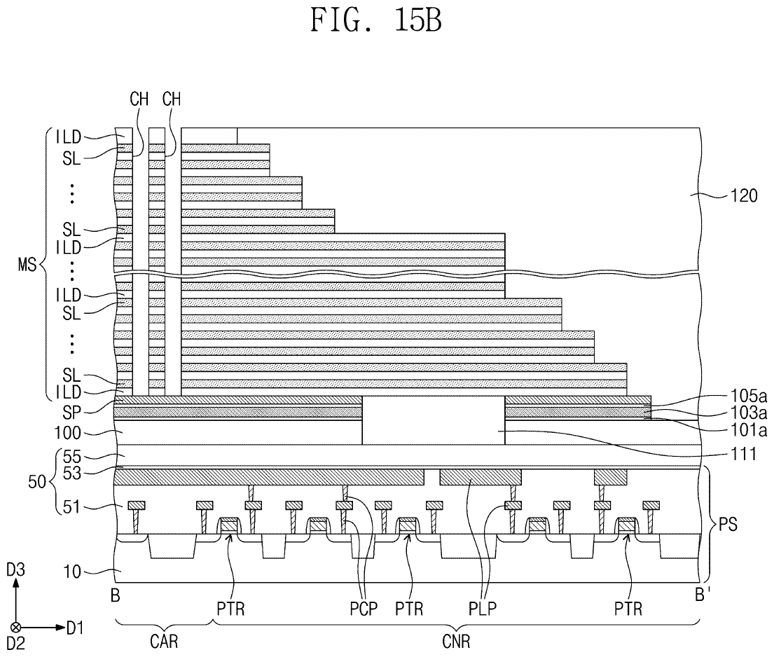

Referring to FIGS. 15A and 15B, a mold structure MS may be formed on the conductive supporting pattern SP. The formation of the mold structure MS may include forming a layered structure, in which insulating and sacrificial layers ILD and SL, respectively, are alternately stacked, and repeatedly performing a patterning process on the layered structure. As a result, the mold structure MS may be formed to have a stepwise structure in the connection region CNR.

The sacrificial layers SL may be formed of or include a material having an etch selectivity with respect to the insulating layers ILD. The sacrificial layers SL may include an insulating material different from the insulating layers ILD. The sacrificial layers SL may be formed of or include the same insulating material as the second dummy insulating layer 103a. For example, the sacrificial layers SL may include silicon nitride, and the insulating layers ILD may include silicon oxide.

The planarization insulating layer 120 may be formed in the connection region CNR. The planarization insulating layer 120 may cover a stepwise structure of the mold structure MS. The top surface of the planarization insulating layer 120 may be located at the same level as a top surface of the mold structure MS.

In the cell array region CAR, the channel holes CH may be formed to penetrate (i.e., extend in or through) the mold structure MS. The formation of the channel holes CH may include forming a mask pattern on the mold structure MS and performing an etching process using the mask pattern to expose the side surface of the mold structure MS and the conductive supporting pattern SP. For example, the etching process may be an anisotropic dry etching process, which is performed using plasma, although embodiments are not limited thereto.

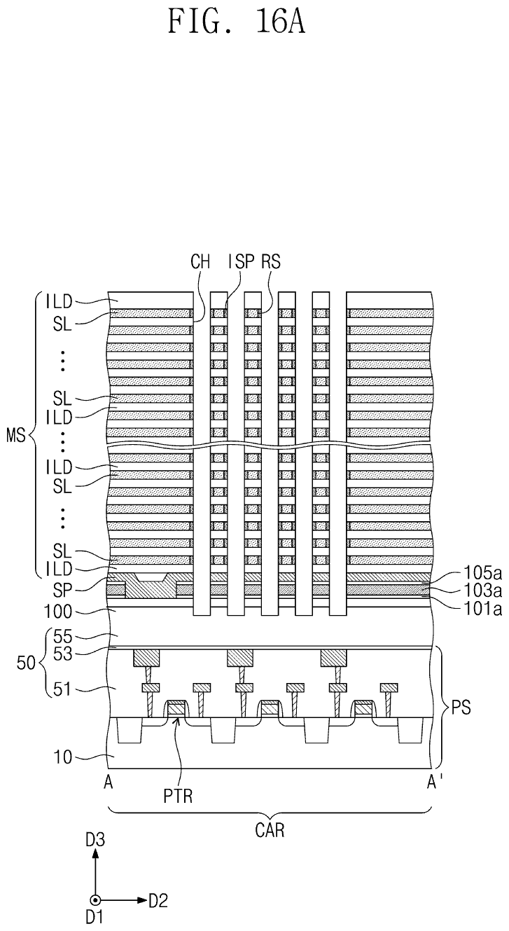

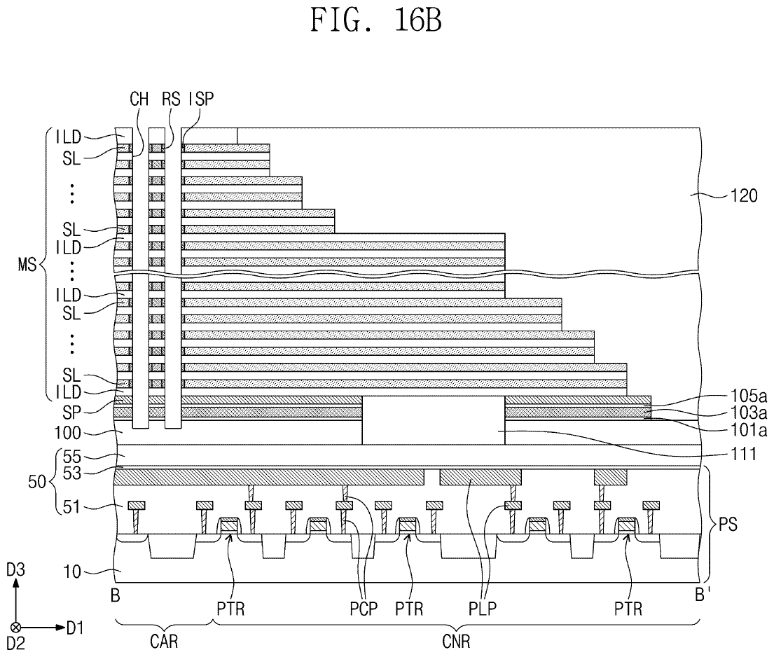

Referring to FIGS. 16A and 16B, the recess regions RS, which are extended from the inner side surfaces of the channel holes CH in a horizontal direction, may be formed. The formation of the recess regions RS may include partially removing the sacrificial layers SL through the channel holes CH. The partial removal of the sacrificial layers SL may be performed by a wet etching process using an etching solution having an etch selectivity. By adjusting the process time or the process temperature in the wet etching process, it may control a removal amount of the sacrificial layers SL. Since the insulating layers ILD are not removed by the wet etching process, the inner side surfaces of the channel holes CH may be formed to have an uneven profile.

Next, an ion storage layer may be formed to cover the inner surfaces of the channel holes CH and the recess regions RS. The ion storage layer may be formed in the channel holes CH and the recess regions RS to have a uniform or constant thickness. Portions of the ion storage layer may be provided to fill the recess regions RS. The ion storage layer may be formed by a deposition process. In an embodiment, the deposition process may include a chemical vapor deposition (CVD) process or an atomic layer deposition (ALD) process.

After the formation of the ion storage layer, an etch-back process may be performed on the mold structure MS. As a result of the etch-back process, the ion storage layer, the conductive supporting pattern SP, the first to third dummy insulating layers 101a, 103a, and 105a, and the second substrate 100 may be partially removed. For example, a portion of the ion storage layer outside the recess regions RS may be removed, and a remaining portion of the ion storage layer may be left in the recess regions RS. Thus, the ion storage patterns ISP, which are the remaining portion of the ion storage layer, may be formed in the recess regions RS. In addition, the conductive supporting pattern SP, the first to third dummy insulating layers 101a, 103a, and 105a, and the second substrate 100 may be exposed through the channel holes CH. Furthermore, a thickness of the uppermost one of the insulating layers ILD may be reduced.

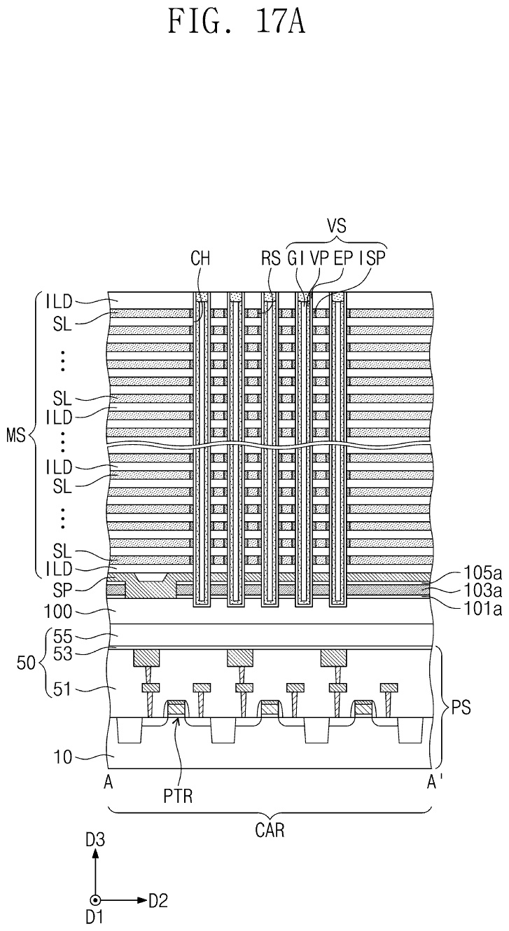

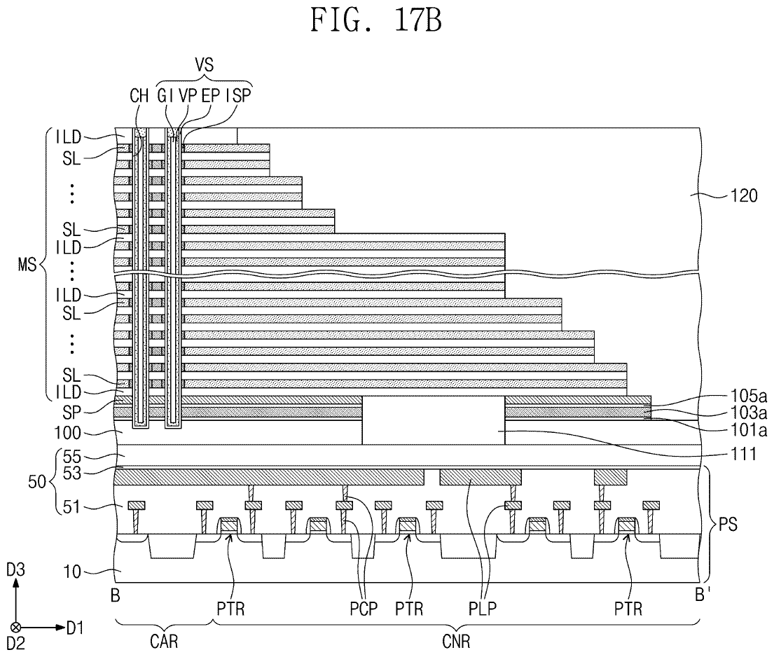

Referring to FIGS. 17A and 17B, the electrolytic pattern EP, the vertical channel pattern VP, and the gapfill insulating pattern GI may be sequentially formed on the inner side surfaces of the channel holes CH. The formation of the electrolytic pattern EP, the vertical channel pattern VP, and the gapfill insulating pattern GI may include etching and planarizing the electrolytic pattern EP, the vertical channel pattern VP, and the gapfill insulating pattern GI. Thus, the vertical structures VS, each of which includes the ion storage patterns ISP, the electrolytic pattern EP, the vertical channel pattern VP, and the gapfill insulating pattern GI, may be formed. The top surfaces of the vertical structures VS may be placed at the same level as the top surface of the mold structure MS, relative to a top surface of the second substrate 100; that is, the top surfaces of the vertical structures VS may be coplanar with the top surface of the mold structure MS.

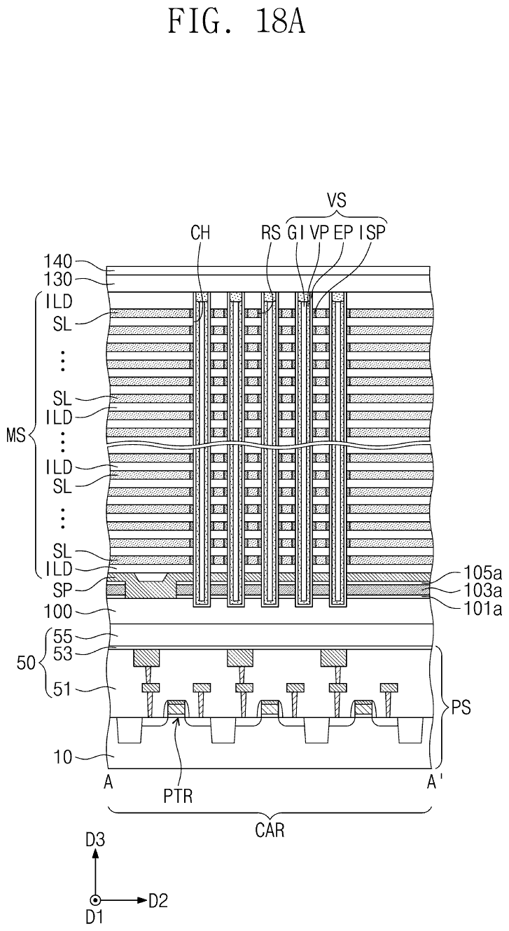

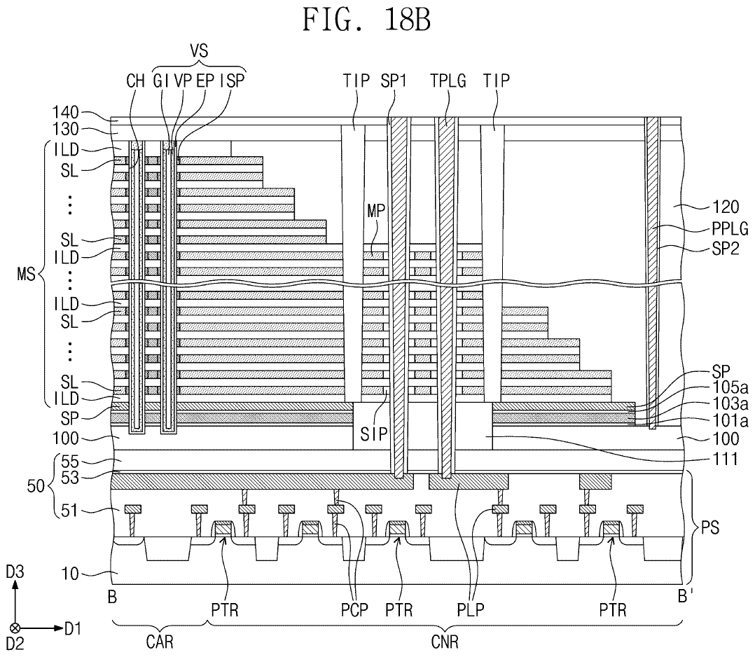

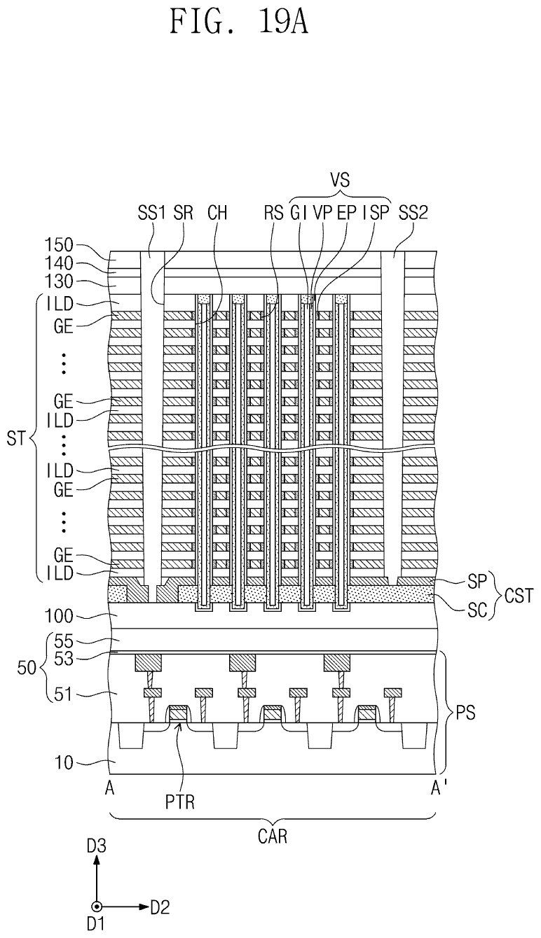

Referring to FIGS. 18A and 18B, the first interlayer insulating layer 130 may be formed on the mold structure MS. The first interlayer insulating layer 130 may cover the top surfaces of the vertical structures VS and the top surface of the planarization insulating layer 120.

The penetration insulating pattern TIP may be formed in the connection region CNR. The formation of the penetration insulating pattern TIP may include forming a trench to penetrate the first interlayer insulating layer 130, the planarization insulating layer 120, and the mold structure MS and filling the trench with an insulating material. When viewed in a plan view, the penetration insulating pattern TIP may have a closed-loop shape enclosing (i.e., extending around or surrounding) the mold insulating pattern 111.

The second interlayer insulating layer 140 may be formed on the first interlayer insulating layer 130. The second interlayer insulating layer 140 may cover a top surface of the first interlayer insulating layer 130 and a top surface of the penetration insulating pattern TIP. Next, the penetration contact plugs TPLG and the peripheral contact plugs PPLG may be formed.

The formation of the penetration contact plugs TPLG may include forming a penetration hole to penetrate the first and second interlayer insulating layers 130 and 140, the planarization insulating layer 120, the mold structure MS, the mold insulating pattern 111, and the second lower insulating layer 55, removing portions of the sacrificial layers SL through the penetration hole to form the sidewall insulating patterns SIP, forming the first spacer SP1 to cover an inner side surface of the penetration hole, and filling the penetration hole with a conductive material. Thus, the penetration contact plugs TPLG may be electrically connected to the peripheral circuit lines PLP of the peripheral circuit structure PS.

The formation of the peripheral contact plugs PPLG may include forming a penetration hole to penetrate the first and second interlayer insulating layers 130 and 140 and the planarization insulating layer 120, forming the second spacer SP2 to cover an inner side surface of the penetration hole, and filling the penetration hole with a conductive material. Here, the peripheral contact plugs PPLG may be formed to be in contact with the second substrate 100.

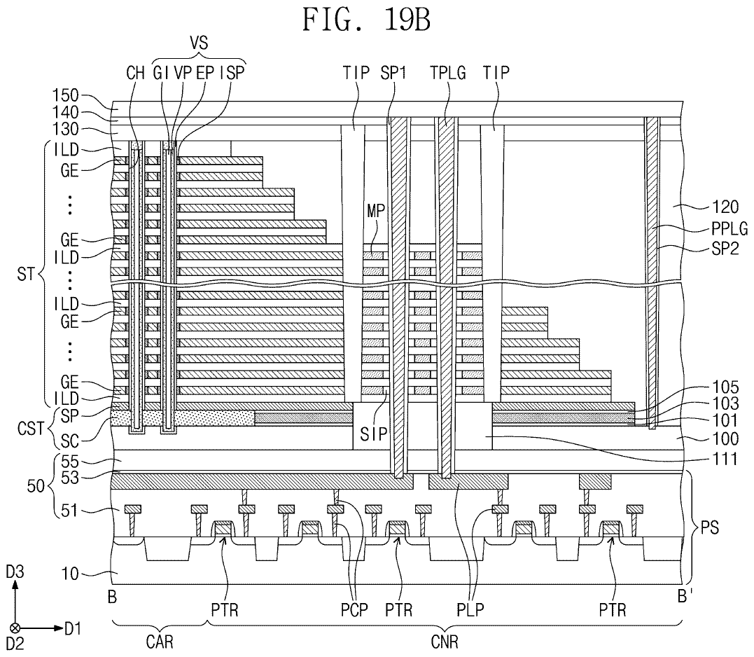

Referring to FIGS. 19A and 19B, the third interlayer insulating layer 150 may be formed on the second interlayer insulating layer 140 to cover the penetration contact plugs TPLG and the peripheral contact plugs PPLG.

Next, separation trenches SR may be formed to penetrate the mold structure MS. The separation trenches SR may be formed by etching the first to third interlayer insulating layers 130, 140, and 150, the planarization insulating layer 120, and the mold structure MS, and the conductive supporting pattern SP may be used as an etch stop layer.

The first to third dummy insulating layers 101a, 103a, and 105a may be partially removed through the separation trenches SR, and the source conductive pattern SC may be formed in an empty space, which is formed by removing the first to third dummy insulating layers 101a, 103a, and 105a. The formation of the source conductive pattern SC may include performing an etching process on the first to third dummy insulating layers 101a, 103a, and 105a and the vertical structures VS, which are exposed by the separation trenches SR. The electrolytic pattern EP of the vertical structure VS may be partially removed to expose the vertical channel pattern VP, as described with reference to FIG. 12. Next, the source conductive pattern SC may be formed by depositing doped polysilicon. Accordingly, the source structure CST may be formed between the second substrate 100 and the mold structure MS.

The gate electrodes GE may be formed, after the formation of the source structure CST. The formation of the gate electrodes GE may include removing the sacrificial layers SL through an etching process using a material having an etch selectivity with respect to the insulating layers ILD, the vertical structures VS, and the source structure CST and filling an empty space, which is formed by removing the sacrificial layers SL, with a conductive material to form the gate electrodes GE. The sacrificial layers SL in the connection region CNR may not be fully removed, and in this case, the remaining portions of the sacrificial layers SL may form the mold patterns MP. As a result, the stack ST may be formed to include the insulating layers ILD and the gate electrodes GE, which are alternately stacked in the third direction D3.

After the formation of the stack ST, the first and second separation structures SS1 and SS2 may be formed by filling the separation trenches SR with an insulating material.

Referring back to FIGS. 6A and 6B, the fourth interlayer insulating layer 160 covering the third interlayer insulating layer 150, the bit line contact plugs BCTa and BCTb connected to the vertical structures VS, the cell contact plugs CPLG connected to the pad portions GEp of the gate electrodes GE, and the contact plugs LCT may be formed. Next, the bit lines BL and the conductive lines CL may be formed on the fourth interlayer insulating layer 160.

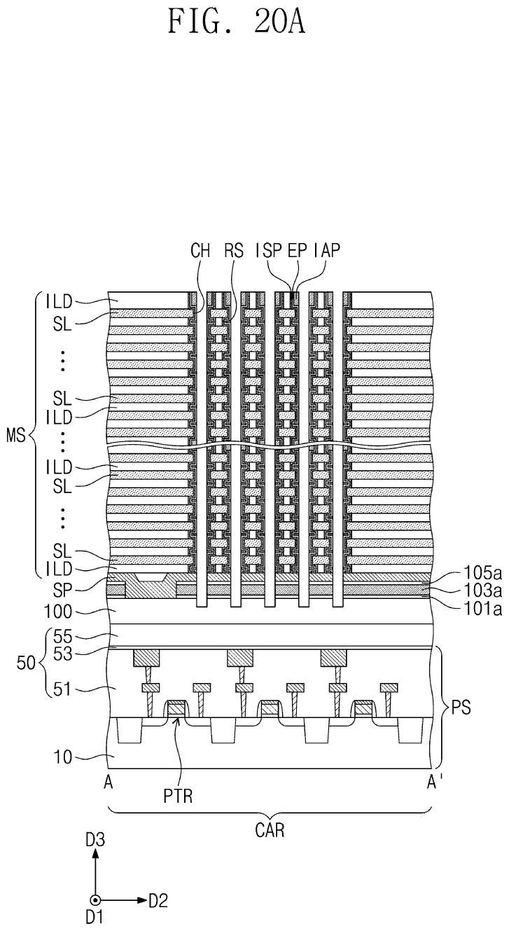

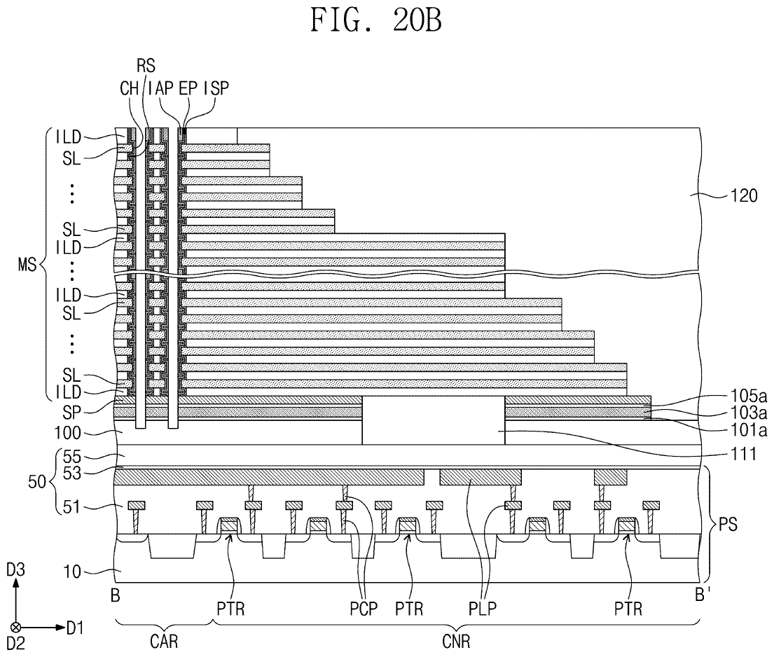

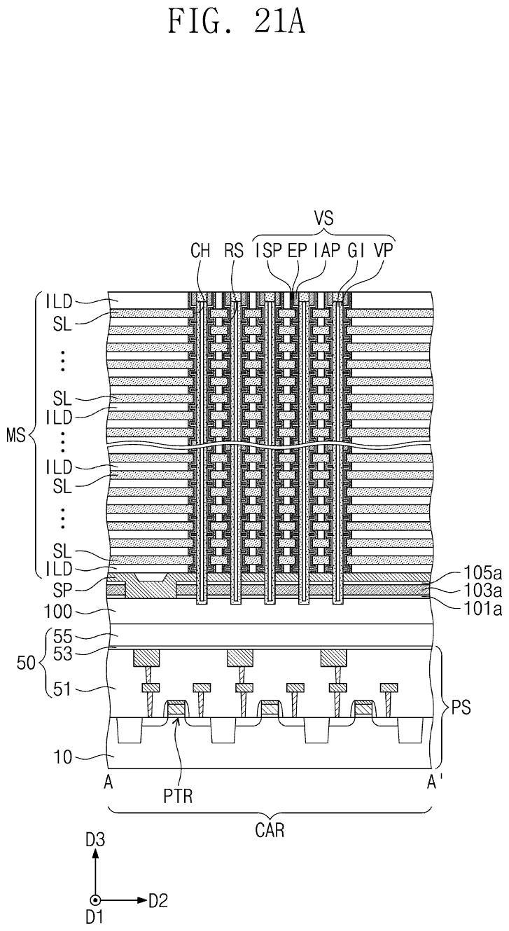

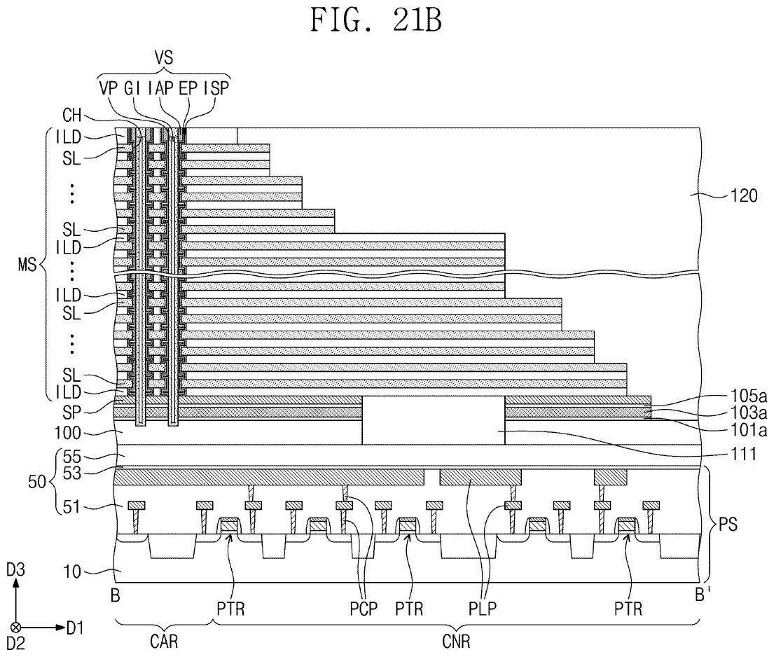

FIGS. 20A to 21B are schematic cross-sectional views illustrating intermediate processes in an example method of fabricating a three-dimensional semiconductor memory device according to an embodiment of the inventive concept. Each of FIGS. 20A and 21A is a sectional view taken along the line A-A′ of FIG. 5, and each of FIGS. 20B and 21B is a sectional view taken along the line B-B′ of FIG. 5.

Referring to FIGS. 20A and 20B, the peripheral circuit structure PS may be formed, the mold structure MS may be formed on the peripheral circuit structure PS, and the channel holes CH may be formed to penetrate the mold structure MS. The peripheral circuit structure PS may be formed by substantially the same method as described with reference to FIGS. 14A and 14B. The mold structure MS and the channel holes CH may be formed by substantially the same method as described with reference to FIGS. 15A and 15B.

The recess regions RS may be formed to have a shape that is recessed from the inner side surfaces of the channel holes CH in a horizontal direction. The formation of the recess regions RS may include partially removing the insulating layers ILD through the channel holes CH. The partial removal of the insulating layers ILD may be performed by a wet etching process using an etching solution having an etch selectivity. By adjusting the process time or the process temperature in the wet etching process, it may control an amount of the insulating layers ILD removed. Since the sacrificial layers SL are not removed by the wet etching process, the inner side surfaces of the channel holes CH may be formed to have an uneven profile.

Next, an ion storage layer, an electrolyte layer, and an ion absorption layer may be sequentially formed on inner surfaces of the channel holes CH and the recess regions RS. Each of the ion storage layer, the electrolyte layer, and the ion absorption layer may be formed in the channel holes CH and the recess regions RS to have a uniform or constant thickness. For example, the ion absorption layer may be thicker than the ion storage layer and the electrolyte layer. In an embodiment, the ion storage layer, the electrolyte layer, and the ion absorption layer may be formed by a deposition process. In an embodiment, the deposition process may include a chemical vapor deposition (CVD) process or an atomic layer deposition (ALD) process.

After the formation of the ion absorption layer, an etch-back process may be performed on the mold structure MS. The ion storage layer, the electrolyte layer, the ion absorption layer, the conductive supporting pattern SP, the first to third dummy insulating layers 101a, 103a, and 105a, and the second substrate 100 may be partially removed through the etch-back process. Thus, the ion storage pattern ISP may be formed from the ion storage layer, the electrolytic pattern EP may be formed from the electrolyte layer, and the ion absorption patterns IAP may be formed from the ion absorption layer. Each of the ion absorption patterns IAP may be placed in a corresponding one of the recess regions RS. In addition, the conductive supporting pattern SP, the first to third dummy insulating layers 101a, 103a, and 105a, and the second substrate 100 may be exposed through the channel holes CH.

Referring to FIGS. 21A and 21B, the vertical channel pattern VP and the gapfill insulating pattern GI may be formed to fill each of the channel holes CH. The formation of the vertical channel pattern VP and the gapfill insulating pattern GI may include sequentially forming the vertical channel pattern VP and the gapfill insulating pattern GI on the electrolytic pattern EP and the ion absorption patterns IAP and etching and planarizing the vertical channel pattern VP and the gapfill insulating pattern GI. Thus, the vertical structures VS, each of which includes the ion storage pattern ISP, the electrolytic pattern EP, the ion absorption patterns IAP, the vertical channel pattern VP, and the gapfill insulating pattern GI, may be formed.

Thereafter, other elements may be formed, as described with reference to FIGS. 18A to 19B.

According to an embodiment of the inventive concept, a three-dimensional semiconductor memory device may include ion storage patterns, which are spaced apart from each other in a vertical direction and are physically separated from each other, or which are spaced apart from each other in a vertical direction by an ion absorption pattern and are chemically separated from each other. Accordingly, it may prevent a carrier of the ion storage pattern from moving in a vertical or diagonal direction. Thus, the electrical characteristics of the three-dimensional semiconductor memory device may be improved.

While example embodiments of the inventive concept have been particularly shown and described, it will be understood by one of ordinary skill in the art that variations in form and detail may be made therein without departing from the spirit and scope of the attached claims.

What is claimed is:

1. A three-dimensional (3D) semiconductor memory device, comprising:
a stack including gate electrodes and insulating layers, which are alternately stacked on a substrate;
a vertical channel pattern in a channel hole extending in a vertical direction perpendicular to a top surface of the substrate in the stack;
an ion storage pattern on a side surface of the vertical channel pattern;
an electrolytic pattern between the vertical channel pattern and the ion storage pattern; and
ion absorption patterns between the vertical channel pattern and the electrolytic pattern,
wherein each of the ion storage pattern and the electrolytic pattern extends in the vertical direction, and
the ion absorption patterns are spaced apart from each other in the vertical direction.

2. The 3D semiconductor memory device of claim 1, wherein each of the ion absorption patterns is located at a same level in the vertical direction as a corresponding one of the insulating layers, relative to the top surface of the substrate.

3. The 3D semiconductor memory device of claim 1, wherein each of the ion absorption patterns extends around the vertical channel pattern, when viewed in a plan view.

4. The 3D semiconductor memory device of claim 1, wherein at least a portion of the electrolytic pattern is in contact with the vertical channel pattern.

5. The 3D semiconductor memory device of claim 1, wherein the electrolytic pattern comprises oxygen vacancies,
the ion storage pattern comprises oxygen ions, and
the ion absorption patterns are configured to absorb the oxygen ions.

6. The 3D semiconductor memory device of claim 1, wherein the ion absorption patterns comprise at least one of titanium (Ti), cadmium (Cd), or cobalt (Co).

7. The 3D semiconductor memory device of claim 1, wherein at least a portion of the electrolytic pattern is in contact with the ion absorption patterns.

8. The 3D semiconductor memory device of claim 1, wherein the ion absorption patterns are spaced apart from the gate electrodes in the vertical direction.

9. A three-dimensional (3D) semiconductor memory device, comprising:
a stack including gate electrodes and insulating layers, which are alternately stacked on a substrate;
a vertical channel pattern in a channel hole extending in a vertical direction perpendicular to a top surface of the substrate in the stack;
ion storage patterns on a side surface of the vertical channel pattern; and
an electrolytic pattern between the vertical channel pattern and the ion storage patterns,
wherein the ion storage patterns are spaced apart from each other in the vertical direction.

10. The 3D semiconductor memory device of claim 9, wherein the electrolytic pattern comprises oxygen vacancies, and
the ion storage patterns comprise oxygen ions.

11. The 3D semiconductor memory device of claim 9, wherein each of the ion storage patterns extends around the electrolytic pattern, when viewed in a plan view.

12. The 3D semiconductor memory device of claim 9, wherein each of the ion storage patterns is in a recess region extending in a horizontal direction, parallel to the top surface of the substrate, from an inner side surface of the channel hole.

13. The 3D semiconductor memory device of claim 9, wherein the electrolytic pattern extends in the vertical direction in the channel hole.

14. The 3D semiconductor memory device of claim 9, wherein the electrolytic pattern comprises a plurality of electrolytic patterns, and
wherein the plurality of electrolytic patterns are spaced apart from each other in the vertical direction.

15. The 3D semiconductor memory device of claim 14, wherein each of the plurality of electrolytic patterns is at a same level in the vertical direction as a corresponding one of the ion storage patterns.

16. The 3D semiconductor memory device of claim 14, wherein each of the plurality of electrolytic patterns extends to top and bottom surfaces of a respective one of the ion storage patterns.

17. The 3D semiconductor memory device of claim 16, wherein at least a portion of each of the ion storage patterns is in contact with the vertical channel pattern.

18. An electronic system, comprising:
a three-dimensional (3D) semiconductor memory device, the 3D semiconductor memory device comprising: a substrate including a cell array region and a connection region; a peripheral circuit structure including peripheral circuits on the substrate; a cell array structure including a stack including gate electrodes and insulating layers, which are alternately stacked on the peripheral circuit structure in a vertical direction perpendicular to a top surface of the substrate;
vertical structures extending in the vertical direction in the stack; and an input/output pad electrically connected to the peripheral circuits; and
a controller electrically connected to the 3D semiconductor memory device through the input/output pad and configured to control the 3D semiconductor memory device,
wherein each of the vertical structures comprises:
a vertical channel pattern in a channel hole extending in the vertical direction in the stack;
an ion storage pattern on a side surface of the vertical channel pattern;
an electrolytic pattern between the vertical channel pattern and the ion storage pattern; and
ion absorption patterns between the vertical channel pattern and the electrolytic pattern,
wherein the ion absorption patterns are spaced apart from each other in the vertical direction.

19. The electronic system of claim 18, wherein each of the ion absorption patterns extends around the vertical channel pattern, when viewed in a plan view, and
at least a portion of the electrolytic pattern is in contact with the vertical channel pattern.

20. The electronic system of claim 18, wherein the electrolytic pattern comprises oxygen vacancies,
the ion storage pattern comprises oxygen ions, and
the ion absorption patterns are configured to absorb the oxygen ions.
